(19) United States
(12) Patent Application Publication
(10) Pub. No.: US 2026/0333804 A1
(43) Pub. Date: Oct. 22, 2026

(54) TRANSISTOR, SEMICONDUCTOR DEVICE AND MANUFACTURING METHOD OF SEMICONDUCTOR DEVICE

(71) Applicant: Taipei ANJET Corporation, Taipei (TW)

(72) Inventors: Yasuo Kitahira, Kyoto-city (JP); Yuji Kiuchi, Kyoto-city (JP); Cheng Hou Chan, Kyoto-city (JP); Wen-Chin WU, Taipei City (TW)

(21) Appl. No.: 19/182,650

(22) Filed: Apr. 18, 2025

(51) Int. Cl. H10D 62/17; H10D 30/01; H10D 30/66; H10D 62/00; H10D 62/10

(52) U.S. Cl. CPC H10D 62/371; H10D 30/0291; H10D 30/665; H10D 62/01; H10D 62/107; H10D 62/127

(57) ABSTRACT

A transistor is provided and includes a substrate, an epitaxial layer, two well regions, two source regions and a body contact region. The epitaxial layer is disposed on the substrate. The two well regions are separately disposed in the epitaxial layer. The two source regions are respectively disposed in the two well regions. The body contact region is disposed in each well region and is located under the two source regions. By the aforementioned configuration, each source region is located on the body contact region and has at least one side without contacting the body contact region, thereby reducing the lateral spreading current of the transistor and shortening the channel of the transistor.

### TECHNICAL FIELD OF THE INVENTION

The present disclosure is related to the technical of semiconductor and is particularly directed to a transistor, a semiconductor device and a manufacturing method of a semiconductor device.

### DESCRIPTION OF THE PRIOR ART

As environment awareness increases, electric vehicles (EVs) boom. The EVs boom drives the requirements of electricity and power converters. The power converters would utilize numerous power transistors such as power metal oxide semiconductor field effect transistors (MOSFETs), insulated gate bipolar transistors (IGBTs) and super junction MOSFETs (SJ-MOSFET).

In the power MOSFETs, double diffusion MOSFETs (DMOSFETs) have numerous advantages such as a high threshold voltage and large operation regions and thus are widely used. Several approaches have been taken to reduce the on resistance of the DMOSFET. However, when the on resistance of the DMOSFET is decreased, the short circuit robustness of the DMOSFET become lower. Hence, there is the trade-off relationship between the short circuit robustness and the on resistance of the DMOSFET. It is difficult to improve both the short circuit robustness and the on resistance of the DMOSFET.

### SUMMARY

In light of the aforementioned descriptions, the present disclosure provides a transistor, a semiconductor device and a manufacturing method of a semiconductor device to solve the problem of the trade-off relationship between the short circuit robustness and the on resistance of the DMOSFET.

Based on the aforementioned descriptions, the present disclosure is to provide a transistor. The transistor includes a substrate, an epitaxial layer, two well regions, two source regions and a body contact region. The epitaxial layer is disposed on the substrate. The two well regions are separately disposed in the epitaxial layer. The two source regions are respectively disposed in the two well regions. The body contact region is disposed in each well region and is located under the two source regions.

Based on the aforementioned descriptions, the present disclosure is to provide a transistor. The transistor includes a substrate, an epitaxial layer, two well regions, two source regions, a body contact region and an auxiliary doping source region. The epitaxial layer is disposed on the substrate. The two well regions are separately disposed in the epitaxial layer. The body contact region is disposed in each well region and is located underneath the two source regions. The auxiliary doping source region is disposed between the two source regions and the body contact region, and the doping concentration of the auxiliary doping region is greater than the doping concentration of each source region.

Based on the aforementioned descriptions, the present disclosure is to provide a semiconductor device. The semiconductor device includes a substrate, an epitaxial layer, a plurality of first transistors and a plurality of second transistors. The epitaxial layer is disposed on the substrate and has a plurality of first zones and a plurality of second zones. The plurality of first transistors are disposed on the plurality of first zones, and each first transistor includes two first well regions, two first source regions and a first body contact region. The two first well regions are separately disposed in the first zone of the epitaxial layer. The two first source regions are respectively disposed in the two first well regions. The first body contact region is disposed in each first well region and is located under the two first source regions. The plurality of second transistors are disposed on the plurality of second zones, and each second transistor includes two second well regions, two second source regions, a second body contact region and an auxiliary doping source region. The two second well regions are separately disposed in the second zone of the epitaxial layer. The two second source regions are respectively disposed in the two second well regions. The second body contact region is disposed in each second well region and is located under the two second source regions. The auxiliary doping source region is disposed between the two second source regions and the second body contact region, and the doping concentration of the auxiliary doping region is greater than the doping concentration of each second source region. By arranging the plurality of first transistors and the plurality of second transistors alternately, four sides of the first body contact region are surrounded by the two first source regions and the two auxiliary doping source regions.

Based on the aforementioned descriptions, the present disclosure is to provide a manufacturing method of a semiconductor device. The manufacturing method of the semiconductor device includes: forming an epitaxial layer on a substrate; forming a plurality of well regions in the epitaxial layer; forming a plurality of source regions in the plurality of well regions; forming a plurality of body contact regions in the plurality of well regions; forming a plurality of auxiliary doping source regions in the corresponding body contact regions, wherein a doping concentration of the auxiliary doping region is greater than a doping concentration of each of the plurality of source regions; partially etching the plurality of source regions. Each body contact region is located underneath the two source regions, and each auxiliary doping source region is disposed between the corresponding body contact region and the two corresponding source regions.

Based on the aforementioned descriptions, the present disclosure is to provide a manufacturing method of a semiconductor device. The manufacturing method of the semiconductor device includes: forming a first epitaxial layer on a substrate; forming a plurality of body contact regions in the first epitaxial layer; forming an auxiliary layer on the epitaxial layer, wherein the auxiliary layer covers the plurality of body contact regions; forming a second epitaxial layer on the auxiliary layer; forming a plurality of well regions in the second epitaxial layer, wherein the plurality of well regions encompass the plurality of body contact regions; forming a plurality of source regions in the plurality of well regions; forming an auxiliary doping source region in the corresponding body contact region, wherein the auxiliary doping source region extends from the corresponding source region to the corresponding body contact region; and partially etching the plurality of source regions, wherein each of the plurality of body contact regions is located under the corresponding two source regions.

In view of the above description, in the transistor, the semiconductor device and the manufacturing method of the semiconductor device provided by the present disclosure, the body contact region is located underneath the two corresponding source regions and has at least one side without contacting the source region. In other words, each source region is located on the body contact region and has at least one side without contacting the body contact region. Hence, the semiconductor device and the manufacturing method of the semiconductor device provided by the present disclosure can reduce the lateral spreading current of the transistor and shortening the channel of the transistor.

The aforementioned description of the present disclosure is merely the outline of the technical solutions of the present disclosure. In order to understand the technical solutions of the present disclosure clearly and to implement the present disclosure according to the content of the specification, the better embodiments of the present disclosure given herein below with accompanying drawings are used to describe the present disclosure in detail.

### BRIEF DESCRIPTION OF DRAWINGS

FIG. 1 depicts the top view diagram of a semiconductor device according to one embodiment.

FIG. 2A depicts the cross section diagram sectioned from A-A′ line of FIG. 1.

FIG. 2B depicts the cross section diagram sectioned from B-B′ line of FIG. 1.

FIG. 3 depicts the cross section diagram of DMOSFET in the prior art.

FIG. 4 depicts the top view diagram of a semiconductor device according to another embodiment.

FIG. 5 depicts the cross section diagram sectioned from C-C′ line of FIG. 4.

FIG. 6 depicts the flowchart of a manufacturing method of a semiconductor device according to one embodiment.

FIG. 7A to FIG. 7F depict the cross section diagram of the manufacturing method of the semiconductor device at different stages according to one aspect of FIG. 6.

FIG. 8A to FIG. 8E depict the cross section diagram of the manufacturing method of the semiconductor device at different stages according to another aspect of FIG. 6.

FIG. 9 depicts the flowchart of a manufacturing method of a semiconductor device according to another embodiment.

FIG. 10A to FIG. 10C depict the cross section diagram of the manufacturing method of the semiconductor device at different stages according to one aspect of FIG. 9.

FIG. 11A and FIG. 11B depict the flowchart of a manufacturing method of a semiconductor device according to yet another embodiment.

FIG. 12A to FIG. 12K depict the cross section diagram of the manufacturing method of the semiconductor device at different stages according to one aspect of FIG. 11A and FIG. 11B.

FIG. 13A and FIG. 13B depict the flowchart of a manufacturing method of a semiconductor device according to still another embodiment.

FIG. 14A to FIG. 14L depict the cross section diagram of the manufacturing method of the semiconductor device at different stages according to one aspect of FIG. 12A and FIG. 12B.

### DETAILED DESCRIPTION

The specific embodiments of the present disclosure given herein below is used to explain the implementation of the present disclosure. A person skilled in the art easily understands the advantages and the effects of the present disclosure from the content of the present disclosure.

It should be noted that the embodiments and the features in the embodiments of the present disclosure can be combined with each other without conflict. The present disclosure will be described in detail below with reference to accompanying drawings and in conjunction with the embodiments. In order to provide those in the art with better understanding of the solution of the disclosure, the technical solutions in the embodiments of the present disclosure will be described clearly and completely below in conjunction with the accompanying drawings in the embodiments of the present disclosure. Apparently, the described embodiments are merely one part of the embodiments of the present disclosure and not all embodiments of the present disclosure. Based on the embodiments of the present disclosure, all embodiments obtained by a person skilled in the art without any inventive steps shall fall within the scope of protection of the present disclosure.

It should be noted that the terms “first”, “second”, etc. in the specification and claims of the present disclosure and in the aforementioned accompanying drawings are used to distinguish similar objects and not used to describe a particular order or sequence. Furthermore, the terms “comprising” and “having”, and any variation thereof, are intended to encompass a non-exclusive inclusion, for example, a series of steps or units comprising processes, methods, systems, products or equipment do not need to be limited to those steps or units clearly listed but may include other steps or units not clearly listed or inherent to those processes, methods, products or equipment.

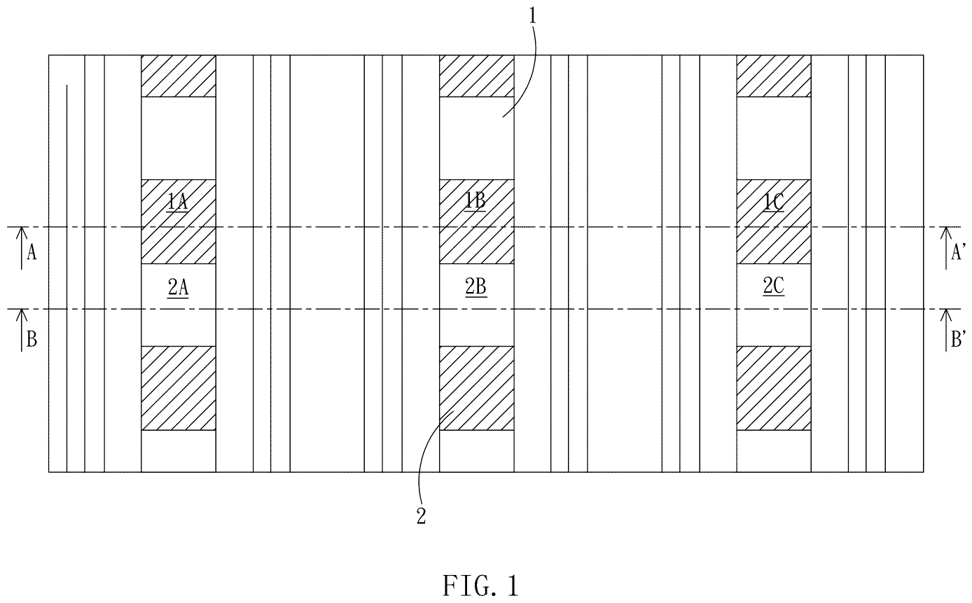

Please refer to FIG. 1, which depicts the top view diagram of a semiconductor device according to one embodiment. As shown in FIG. 1, a semiconductor device includes a plurality of first transistors 1 and a plurality of second transistors 2. The plurality of first transistors 1 are arranged in rows, and the plurality of second transistors 2 are arranged in rows. The rows of the first transistors 1 and the rows of the second transistors 2 are alternate in sequence. For example, there are two rows of first transistors 1 and two rows of the second transistors 2, and the row of the second transistors 2 is between the corresponding two rows of first transistors 1.

Each first transistor 1 and each second transistor 2 may be a MOSFET, a IGBT or a SJ-MOSFET, and the first transistor 1 and the second transistor 2 may be the other types of power transistors. For example, each first transistor 1 and each second transistor 2 may be the MOSFET, and the type of MOSFET may be but not be limited to a planar type, a trench type or a stripe pattern and a cell pattern.

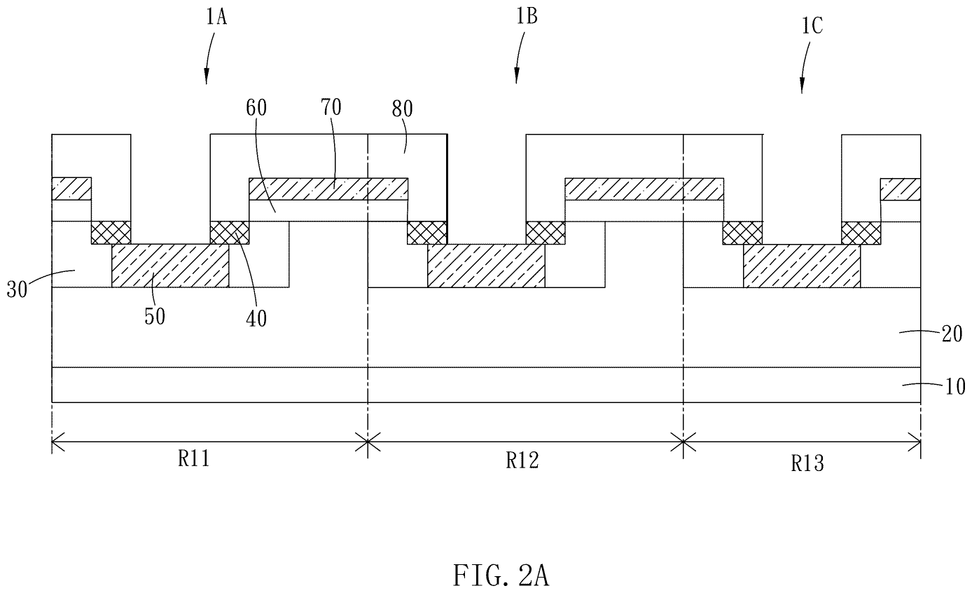

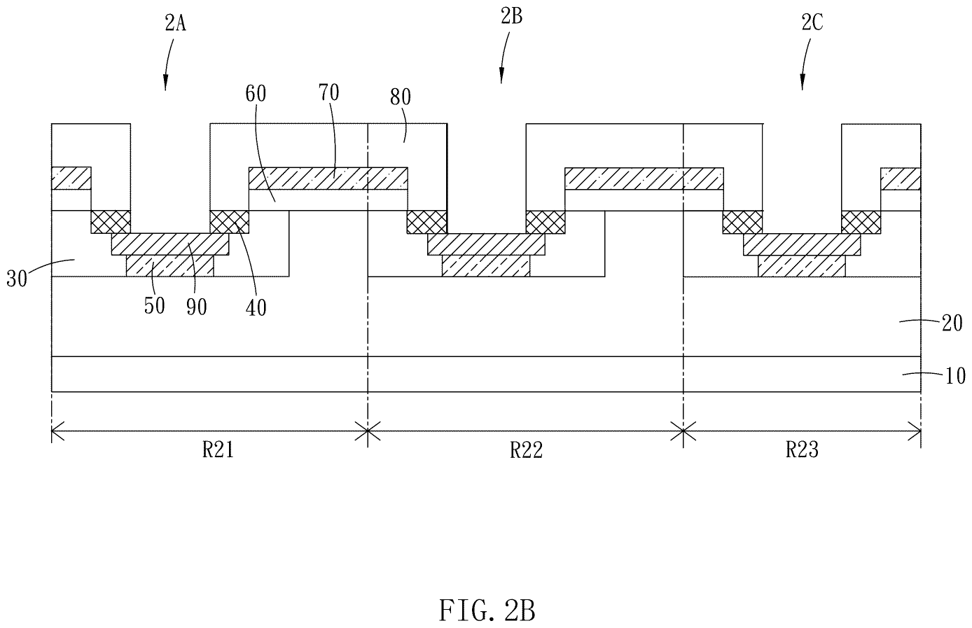

Please refer to FIG. 2A, which depict the cross section diagram sectioned from A-A′ line of FIG. 1. As show in FIG. 2A, one row of first transistors 1 has three first transistors for example, and three first transistors are arranged side by side and are denoted by 1A, 1B and 1C. Each of three first transistor 1A, 1B and 1C includes a substrate 10, an epitaxial layer 20, two well regions 30, two source regions 40 and a body contact region 50. Specifically, the substrate 10 has a plurality of first zones, and for example, the number of first zones is three, and three first zones are denoted by R11, R12 and R13. The epitaxial layer 20 is disposed on the substrate 10. The first transistors 1A, 1B and 1C are disposed on the first zones R11, R12 and R13 of the epitaxial layer 20, and the well regions 30, the source regions 40 and the body contact regions 50 of the first transistors 1A, 1B and 1C respectively lie within the first zones R11, R12 and R13. The following would elaborate the configuration of the first transistor 1A, and the configurations of the first transistors 1B and 1C are the same as the configuration of the first transistor 1A and would not be repeated.

The substrate 10 may be but not be limited to a Si substrate or a SiC substrate, and the type of the substrate 10 may be a first type conductivity or a second type conductivity, wherein the first type conductivity is one of a p-type and a n-type and the second type conductivity is the other of the p-type and the n-type. In the present embodiment, the first type conductivity is the n-type, and the second type conductivity is the p-type, and the type of the substrate 10 is the first type conductivity.

In the present embodiment, the first transistor 1A is the n-type DMOSFET, the source region 40 and the epitaxial layer 20 are the n-type doping regions based on SiC, and the well regions 30 and the body contact region 50 are the p-type doping regions based on SiC. In another embodiment, the first transistor 1A is the p-type DMOSFET, the source regions 40 and the epitaxial layer 20 are the p-type doping regions based on SiC, and the well regions 30 and the body contact region 50 are the n-type doping regions based on SiC.

The epitaxial layer 20 serves as a drift region, and the type of the epitaxial layer 20 is the first type conductivity. Because the substrate 10 has the first zones R11, R12 and R13, and the epitaxial layer 20 is divided into the first zones R11, R12 and R13. The well regions 30, and the source regions 40 and the body contact region 50 of the first transistor 1A lie within the first zone R11.

Two well regions 30 are separately disposed in the first zone R11 of the epitaxial layer 20, and the type of each well region 30 is the second type conductivity. Specifically, each well region 30 extends from the surface of the epitaxial layer 20 and stops in the epitaxial layer 20. Two source regions 40 are respectively disposed in the two well regions 30, and the type of each source region 40 is the first type conductivity. Specifically, each source regions 40 extends from the surface of the epitaxial layer 20 and stops in the corresponding well region 30. In other words, each well region 30 encompass the corresponding source region 40. The orthogonal projection of each well region 30 on the substrate 10 overlaps the orthogonal projection of the corresponding source region 40 on the substrate 10, and the length of the orthogonal projection of each well region 30 on the substrate 10 is greater than the length of the orthogonal projection of the corresponding source region 40 on the substrate 10.

The body contact region 50 is disposed in each well region 30 and is located under two source regions 40, and the type of the body contact region 50 is the second type conductivity. In other words, there is a gap between two source regions 40, and the body contact region 50 is situated on the gap. Specifically, the body contact region 50 extends from the bottom of the source region 40 and stops in the well region 30, and two source regions 40 are located on the body contact region 50 and are situated on the left side and the right side of the body contact region 50. Hence, the body contact region 50 has at least one side without contacting the source region 40, and two source regions 40 encompass the body contact region 50. Correspondingly, each source region 40 has at least one side without contacting the body contact region 50. For example, the top side of the body contact region 50 contacts two source regions 40, and the left side, the right side and the bottom side of the body contact region 50 does not contact two source regions 40; the top side of each source region 40 does not contact the body contact region 50, the right side of one of two source regions 40 does not contact the body contact region 50, and the left side of the other of two source regions 40 does not contact the body contact region 50. The orthogonal projection of the body contact region 50 on the substrate 10 overlaps the orthogonal projection of each source region 40 on the substrate 10, and the length of the orthogonal projection of the body contact region 50 on the substrate 10 is greater than the length of the orthogonal projection of each source region 40 on the substrate 10.

In the present embodiment, the first transistor 1A further includes a gate oxide layer 60. The gate oxide layer 60 is disposed on the epitaxial layer 20 and covers the partial surface of the epitaxial layer 20. Furthermore, the gate oxide layer 60 contact the well region 30. For example, the gate oxide layer 60 includes a first part and a second part. The first part of the gate oxide layer 60 is located on the well region 30 which is situated on the right side of the body contact region 50, while the second part of the gate oxide layer 60 is located on the well region 30 which is situated on the left side of the body contact region 50. The first part of the gate oxide layer 60 contacts the well region 30 situated on the right side of the body contact region 50, while the second part of the gate oxide layer 60 contacts the well region 30 situated on the left side of the body contact region 50. In other words, the orthogonal projection of the first part of the gate oxide layer 60 on the substrate 10 overlaps the orthogonal projection on the substrate 10 of the well region 30 situated on the right side of the body contact region 50, while the orthogonal projection of the second part of the gate oxide layer 60 on the substrate 10 overlaps the orthogonal projection on the substrate 10 of the well region 30 situated on the right side of the body contact region 50. The materials of the gate oxide layer 60 may include an oxide, and the oxide may include but not be limited to SiOₓ, AlOₓ, HfO₂, Y₂O₃, Y₂TiO₅, Yb₂O₃, ZrO₂, TiO₂ or Ta₂O₅.

In the present embodiment, the first transistor 1A further includes a gate electrode 70. The gate electrode 70 is disposed on and covers the gate oxide layer 60. For example, the number of the gate electrodes 70 is two, one of two gate electrodes 70 is located on and covers the first part of the gate oxide layer 60, and the other of two gate electrodes 70 is located on and covers the second part of the gate oxide layer 60. In other words, two gate electrodes 70 are located above the epitaxial layer 20. The orthogonal projection on the substrate 10 of the gate electrode 70 located on the first part of the gate oxide layer 60 overlaps the orthogonal projection on the substrate 10 of the well region 30 situated on the right side of the body contact region 50, while the orthogonal projection on the substrate 10 of the gate electrode 70 located on the second part of the gate oxide layer 60 overlaps the orthogonal projection on the substrate 10 of the well region 30 situated on the left side of the body contact region 50. The materials of the gate electrode 70 may include metal materials, and the metal materials may include but not be limited to Al, TiAL, In, Sn, Au, Pt, In, Zn, Ge, Ag, Pb, Pd, Cu, AuBe, BeGe, Ni, PbSn, Cr, AuZn, Ti, W or TiW.

In the present embodiment, the first transistor 1A further includes a first inter-layer dielectric layer 80. The first inter-layer dielectric layer 80 is disposed on the gate electrode 70 and encompass the gate electrode 70 and the gate oxide layer 60. For example, the first inter-layer dielectric layer 80 includes a first part and a second part. The first part of the first inter-layer dielectric layer 80 is disposed on the gate electrode 70 located on the first part of the gate oxide layer 60, and encompasses the first part of the gate oxide layer 60 and the gate electrode 70 located on the first part of the gate oxide layer 60, and extends to the surface of the epitaxial layer 20. In other words, the first part of the first inter-layer dielectric layer 80 partially covers the epitaxial layer 20 and contact the epitaxial layer 20 and the source region 40 located on the right side of the body contact region 50. The second part of the first inter-layer dielectric layer 80 is disposed on the gate electrode 70 located on the second part of the gate oxide layer 60, and encompasses the second part of the gate oxide layer 60 and the gate electrode 70 located on the second part of the gate oxide layer 60, and extends to the surface of the epitaxial layer 20. In other words, the second part of the first inter-layer dielectric layer 80 partially covers the epitaxial layer 20 and contact the epitaxial layer 20 and the source region 40 located on the right side of the body contact region 50.

The orthogonal projection on the substrate 10 of the first part of the first inter-layer dielectric layer 80 overlaps the orthogonal projection on the substrate 10 of the gate electrode 70 located on the first part of the gate oxide layer 60, the orthogonal projection on the substrate 10 of the first part of the gate oxide layer 60, and the orthogonal projection on the substrate 10 of the source region 40 located on the right side of the body contact region 50. The orthogonal projection on the substrate 10 of the second part of the first inter-layer dielectric layer 80 overlaps the orthogonal projection on the substrate 10 of the gate electrode 70 located on the second part of the gate oxide layer 60, the orthogonal projection on the substrate 10 of the second part of the gate oxide layer 60 and the orthogonal projection on the substrate 10 of the source region 40 located on the left side of the body contact region 50. The materials of the first inter-layer dielectric layer 80 may include the oxide and a nitride, and the nitride may include SiON, SiNₓ, SiCBN, SiCN or SiOCN.

In the first transistor provided by the present embodiment, because the body contact region is located under two source regions and has at least without contacting the source region, two source regions may reduce the lateral spreading current of the transistor to reduce the channel length of the transistor. The body contact region may relax the punch throw between the well region and two source regions during off state and may improve the operational robustness of the transistor, such as unclamped inductor switching (UIS) and voltage switching (dv/dt).

Please refer to FIG. 2B, which depicts the cross section diagram sectioned from B-B′ line of FIG. 1. As shown in FIG. 2B, one row of the second transistors 2 has three second transistors for example, and three second transistors are arranged side by side and are denoted by 2A, 2B and 2C. Each of three second transistor 2A, 2B and 2C includes a substrate 10, an epitaxial layer 20, two well regions 30, two source regions 40, a body contact region 50 and an auxiliary doping source region 90. Specifically, the substrate 10 has a plurality of second zones, and for example, the number of second zones is three, and three second zones are denoted by R21, R22 and R23. The epitaxial layer 20 is disposed on the substrate 10. The second transistor 2A, 2B and 2C are disposed on the second zones R21, R22 and R23 of the epitaxial layer 20, and the well regions 30, the source regions 40, the body contact regions 50 and the auxiliary doping source regions 90 of the second transistors 2A, 2B and 2C respectively lie within the second zones R21, R22 and R23. The following would elaborate the configuration of the second transistor 2A, and the configurations of the second transistors 2B and 2C are the same as the configuration of the second transistor 2A and would not be repeated. The configuration of two well regions 30, two source regions 40, the body contact region 50 of the second transistor 2A is the same as the configuration of two well regions 30, two source regions 40, the body contact region 50 of the first transistor 1A and would not be repeated.

The auxiliary doping source region 90 is disposed between two source regions 40 and the body contact region 50, the type of the auxiliary doping source region 90 is the second type conductivity, and the doping concentration of the auxiliary doping region 90 is greater than the doping concentration of each source region 40. Specifically, the auxiliary doping source region 90 extends from the bottom side of the source region 40 to the top side of the body contact region 50. The auxiliary doping source region 90 is disposed on the body contact region 50 and is located under the two source regions 40, and the two source regions 40 encompass the auxiliary doping source region 90. Hence, the orthogonal projection on the substrate 10 of the auxiliary doping source region 90 overlaps the orthogonal projection on the substrate 10 of the body contact region 50 and the orthogonal projection on the substrate 10 of each source region 40.

In the present embodiment, the second transistor 2A further includes a gate oxide layer 60, a gate electrode 70 and a first inter-layer dielectric layer 80. The gate oxide layer 60, the gate electrode 70 and the first inter-layer dielectric layer 80 of the second transistor 2A are the same as the gate oxide layer 60, the gate electrode 70 and the first inter-layer dielectric layer 80 of the first transistor 1A.

In the second transistor provided by the present embodiment, the auxiliary doping source region is provided to achieve ohmic contact, and the body contact region 50 may stabilize the breakdown voltage of the transistor.

Referring to FIG. 1, FIG. 2A and FIG. 2B again, four sides of the body contact region 50 of the first transistor 1A are surrounded by two source regions 40 of the first transistor 1A, the auxiliary doping source region 90 of the second transistor 2A and the doping source region of the second transistor 2; four sides of the body contact region 50 of the first transistor 1B are surrounded by two source regions 40 of the first transistor 1B, the auxiliary doping source region 90 of the second transistor 2B and the doping source region of the second transistor 2; four sides of the body contact region 50 of the first transistor 1C are surrounded by two source regions 40 of the first transistor 1C, the auxiliary doping source region 90 of the second transistor 2C and the doping source region of the second transistor 2.

Correspondingly, four sides of the body contact region 50 of the second transistor 2A are surrounded by the two source regions 40 of the second transistor 2A, the body contact region 50 of the first transistor 1A and the body contact region of the first transistor 1; four sides of the body contact region 50 of the second transistor 2B are surrounded by the two source regions 40 of the second transistor 2B, the body contact region 50 of the first transistor 1B and the body contact region of the first transistor 1; four sides of the body contact region 50 of the second transistor 2C are surrounded by the two source regions 40 of the second transistor 2C, the body contact region 50 of the first transistor 1C and the body contact region of the first transistor 1.

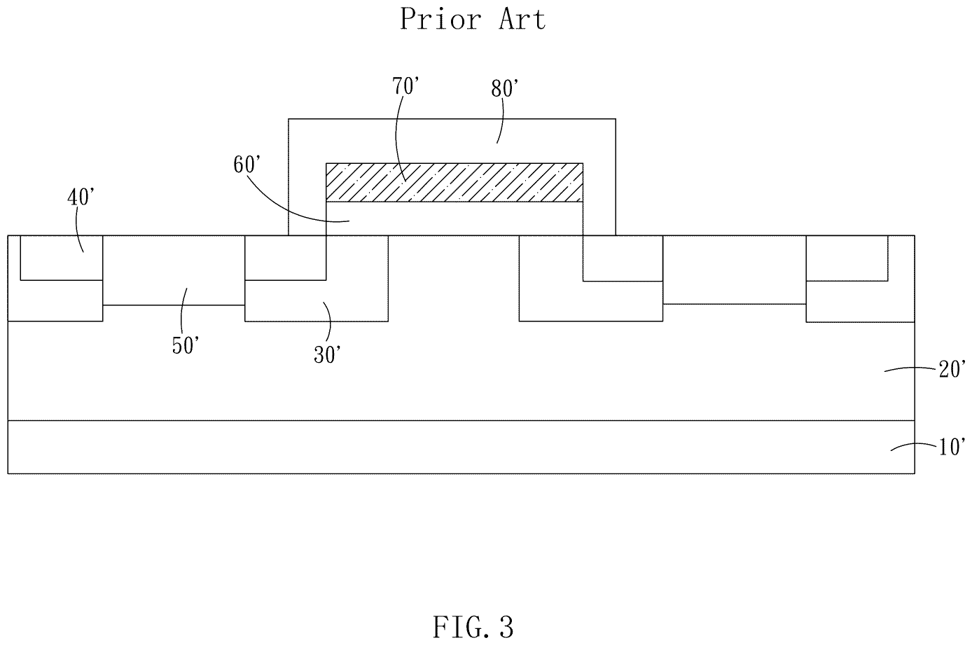

Please refer to FIG. 3, which depicts the cross section diagram of the DMOSFET in the prior art. As shown in FIG. 3, the DMOSFET includes a substrate 10′, an epitaxial layer 20′, two well regions 30′, two source regions 40′, a body contact region 50′, a gate oxide layer 60′, a gate electrode 70′ and an inter-layer dielectric layer 80′. The gate oxide layer 60′, the gate electrode 70′ and the inter-layer dielectric layer 80′ of the DMOSFET are the same as the gate oxide layer 60, the gate electrode 70 and the first inter-layer dielectric layer 80 of the first transistor 1A and would not be repeated. The epitaxial layer 20′ is disposed on the substrate 10, and two well regions 30′, two source regions 40′ and the body contact region 50′ lie within the epitaxial layer 20′. The two source regions 40′ are respectively disposed in two well regions 30′, and the body contact region 50′ is disposed between two source regions 40′. Because the body contact region 50′ is next to the source regions 40′, the lateral spreading current path of the transistor would be generated. Considering the DMOSFET in the prior art, it is difficult to miniaturize (i.e., cell shrink) the DMOSFET. In comparison with the DMOSFET in the prior art, the body contact region 50 of the first transistor 1A provided by the present disclosure has at least one side without contacting the source region 40 to prevent the lateral spreading current of the transistor, and has assistance in reducing the length of the channel in the transistor. Considering that the first transistors 1A to 1C and the second transistors 2A to 2C are alternately arranged, it is beneficial to miniaturizing the DMOSFET.

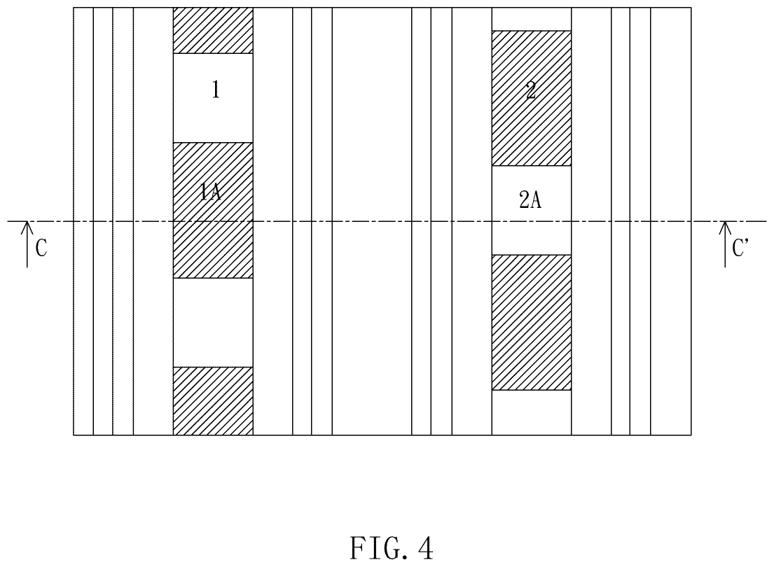

Please refer to FIG. 4, which depicts the top view diagram of a semiconductor device according to another embodiment. As show in FIG. 4, a semiconductor device includes a plurality of first transistors 1 and a plurality of second transistors 2. The configurations of the first transistors 1 and the second transistors 2 shown in FIG. 4 are similar to the configurations of the first transistors 1 and the second transistors 2 shown in FIG. 1, and the similarities between the configurations of FIG. 1 and the configurations of FIG. 4 would not be not repeated.

The plurality of first transistors 1 and the plurality of second transistors 2 in a checkerboard pattern. For example, two second transistors 2 are adjacent to the first transistor 1A, two first transistors 1 are adjacent to the second transistor 2A, and the first transistor 1A and the second transistor 2A are in the same row.

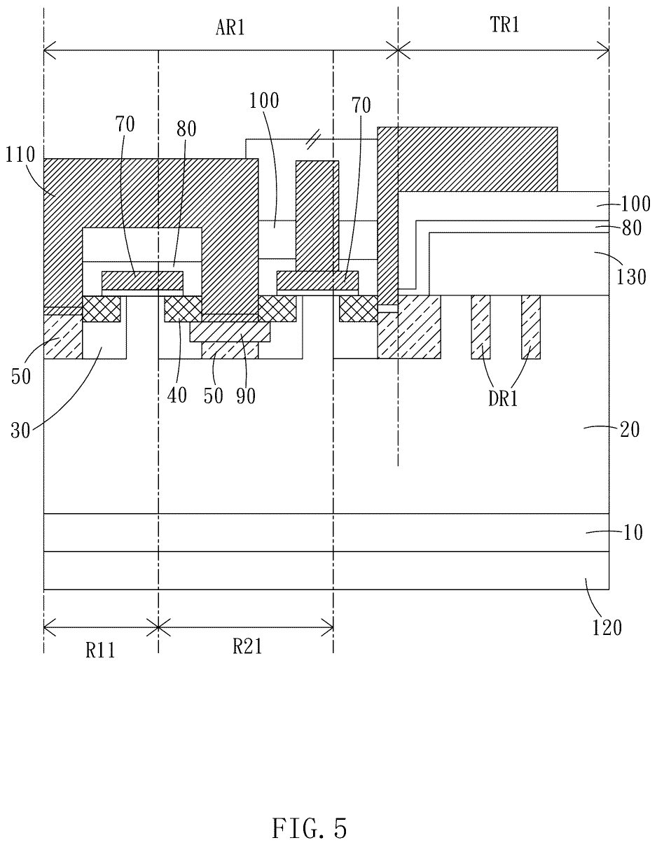

Please refer to FIG. 5, which depicts the cross section diagram sectioned from C-C′ line of FIG. 4. The configurations of the first transistors 1A and the second transistors 2A shown in FIG. 5 are similar to the configurations of the first transistors 1A shown in FIG. 2A and the second transistors 2A shown in FIG. 2B, and the similarities between the configurations of FIG. 2A and FIG. 2B and the configurations of FIG. 5 would not be not repeated.

As shown in FIG. 5, the substrate 10 includes an active area AR1 and a termination area TR1 surrounding the active area AR1. The active area AR1 includes the first zone R11 and the second zone R21, and the second zone R21 is disposed next to the first zone R11. The first transistor 1A is disposed on the first zone R11, and the second transistor 2A is disposed on the second zone R21, i.e., the second transistor 2A is disposed next to the first transistor 1A.

In the present embodiment, both the first transistor 1A and the second transistor 2A may further include a second inter-layer dielectric layer 100. The second inter-layer dielectric layer 100 of the first transistor 1A and the second inter-layer dielectric layer 100 of the second transistor 2A are connected to each other. The second inter-layer dielectric layer 100 of the first transistor 1A is disposed on the first inter-layer dielectric layer 80 of the first transistor 1A, while the second inter-layer dielectric layer 100 of the second transistor 2A is disposed on the first inter-layer dielectric layer 80 of the second transistor 2A. The first inter-layer dielectric layer 80 and the second inter-layer dielectric layer 100 of the second transistor 2A extend to the termination area TR1; the first inter-layer dielectric layer 80 located on the termination area TR1 is disposed on the epitaxial layer 20 located on the termination area TR1, and the second inter-layer dielectric layer 100 located on the termination area TR1 is disposed on the first inter-layer dielectric layer 80 located on the termination area TR1. The materials of the second inter-layer dielectric layer 100 of the first transistor 1A and the second transistor 2A are the same as the materials of the first inter-layer dielectric layer 80 of the first transistor 1A and the second transistor 2A and would be not repeated.

In the present embodiment, both the first transistor 1A and the second transistor 2A may further include a first metal layer 110. The first metal layer 110 of the first transistor 1A is disposed on the second inter-layer dielectric layer 100 of the first transistor 1A, while the first metal layer 110 of the second transistor 2A is disposed on the second inter-layer dielectric layer 100 of the second transistor 2A. One part of the first metal layer 110 of the second transistor 2A is connected to the first metal layer 110 of the first transistor 1A and passes through the second inter-layer dielectric layer 100, the first inter-layer dielectric layer 80 and the gate oxide layer 60 of the second transistor 2A to be connected to the auxiliary doping source region 90 and two source regions 40 of the second transistor 2A, and the other part of the first metal layer 110 of the second transistor 2A passes through the second inter-layer dielectric layer 100 and the first inter-layer dielectric layer 80 of the second transistor 2A to be connected to the gate electrode 70 of the second transistor 2A. The first metal layer 110 of the first transistor 1A passes through the second inter-layer dielectric layer 100, the first inter-layer dielectric layer 80 and the gate oxide layer 60 of the first transistor 1A to be connected to the source region 40 and the body contact region 50 of the first transistor 1A. By the second inter-layer dielectric layer 100 and the first inter-layer dielectric layer 80 of the second transistor 2A, one part of the first metal layer 110 of the second transistor 2A and the other part of the first metal layer 110 of the second transistor 2A are electrically isolated from each other. There is the first metal layer 110 on the termination area TR1, and the first metal layer 110 on the termination area TR1 is disposed on the second inter-layer dielectric layer 100 located on the termination area TR1. By the second inter-layer dielectric layer 100 and the first inter-layer dielectric layer 80 on the termination area TR1, the first metal layer 110 on the termination area TR1 and the first metal layer 110 of the second transistor 2A connected to the gate electrode 70 of the second transistor 2A are electrically isolated from each other. The materials of the first metal layers 110 of the first transistor 1A and the second transistor 2A may include the metal materials.

In the present embodiment, both the first transistor 1A and the second transistor 2A may further include a second metal layer 120. The second metal layer 120 of the first transistor 1A and the second metal layer 120 of the second transistor 2A are disposed under the substrate 10 and are connected to each other. The materials of the second metal layer 120 of the first transistor 1A and the second transistor 2A may include the metal materials.

The semiconductor device may further include a plurality of doping regions DR1. The plurality of doping regions DR1 are disposed on the termination area TR1. Specifically, each doping region DR1 extends from the surface of the epitaxial layer 20 on the termination area TR1 and stops in the epitaxial layer 20 on termination area TR1, and the type of each doping region DR1 is the second type. In other words, each doping regions DR1 lies within the epitaxial layer 20 on the termination area TR1.

The semiconductor device may further include a field oxide layer 130. The field oxide layer 130 are disposed on the termination area TR1. Specifically, the field oxide layer 130 is disposed on the epitaxial layer 20 on the termination area TR1 and is located under the first inter-layer dielectric layer 80 on the termination area TR1. In other words, the field oxide layer 130 is situated between the epitaxial layer 20 on the termination area TR1 and the first inter-layer dielectric layer 80 on the termination area TR1.

In the semiconductor device provided by the present embodiment, the metal layer, the field oxide layer and the doping region on the termination area constitutes a guard ring to improve the breakdown voltage of the semiconductor device.

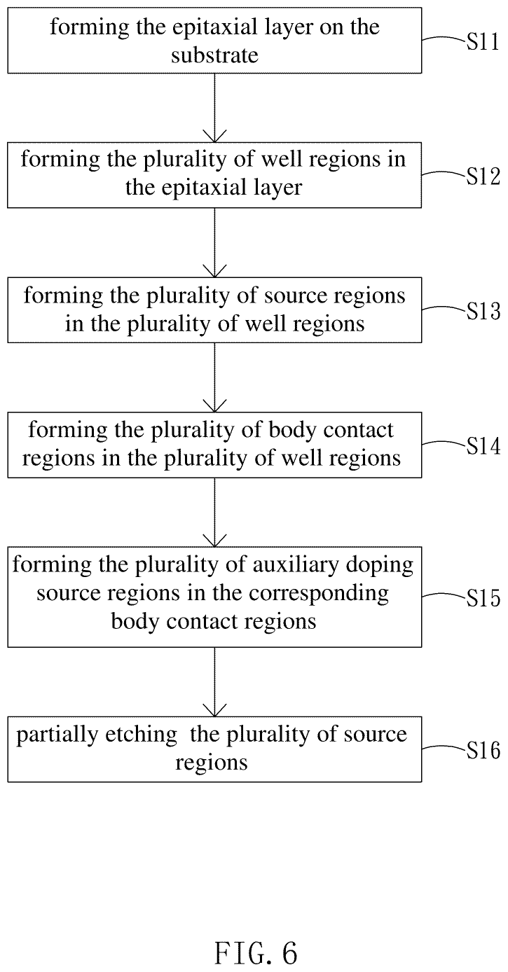

Please refer to FIG. 6, which depicts the flowchart of a manufacturing method of a semiconductor device according to one embodiment. As show in FIG. 6, a manufacturing method of a semiconductor device includes step S11~step S16. The manufacturing method of the semiconductor device shown in FIG. 6 may be applicable to the semiconductor device shown in FIG. 1 to FIG. 2B but be not limited thereto. The step S11~step S16 would be exemplarily explained by the semiconductor device shown in FIG. 1 to FIG. 2B as follows.

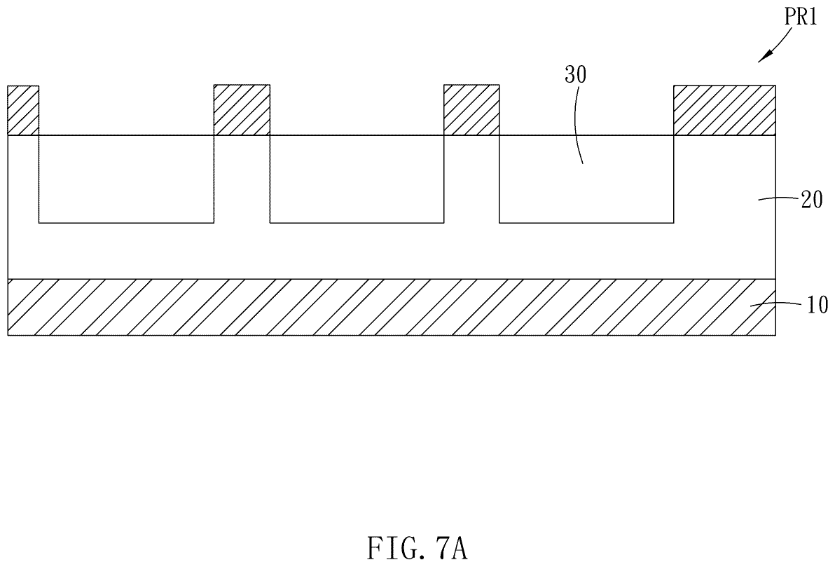

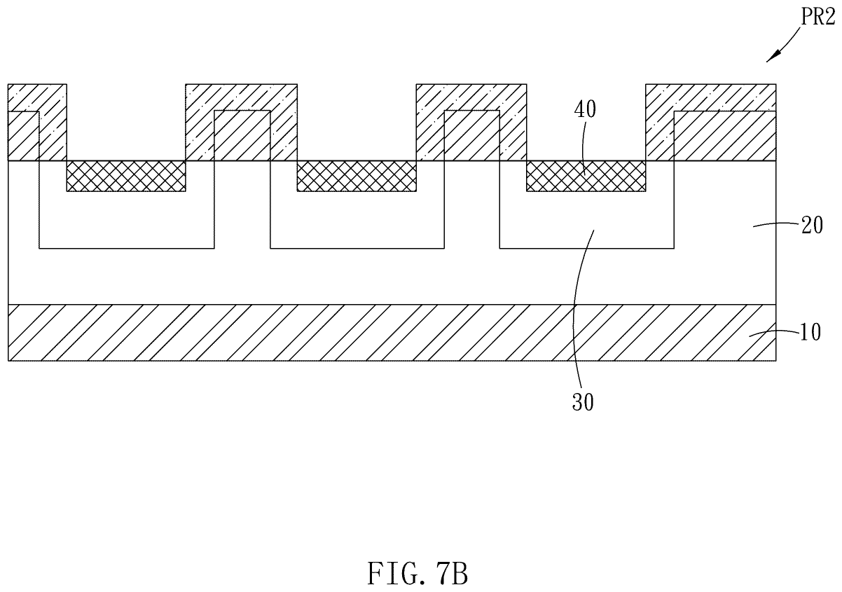

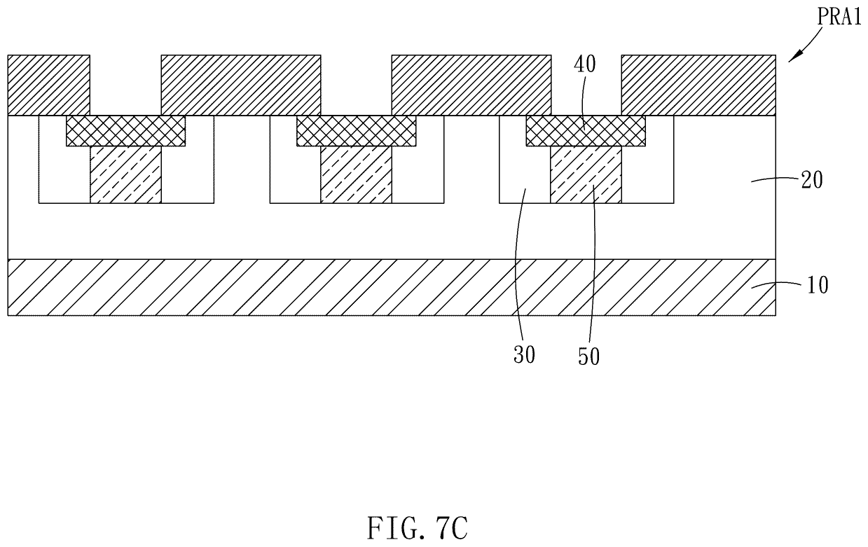

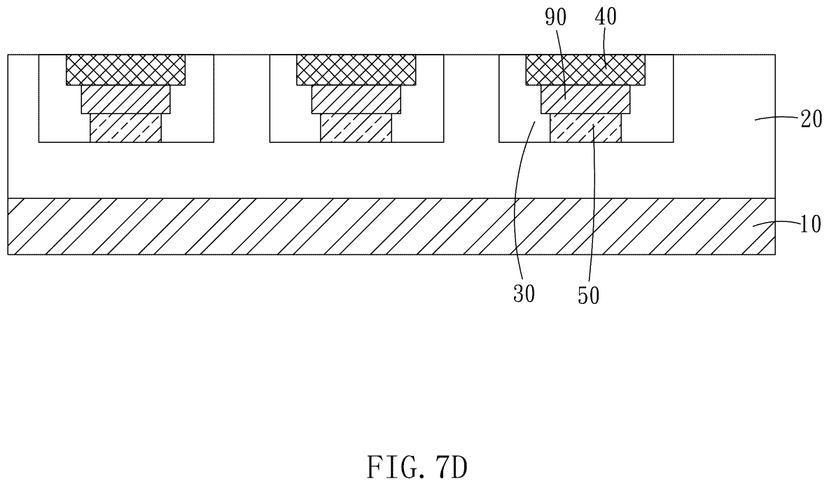

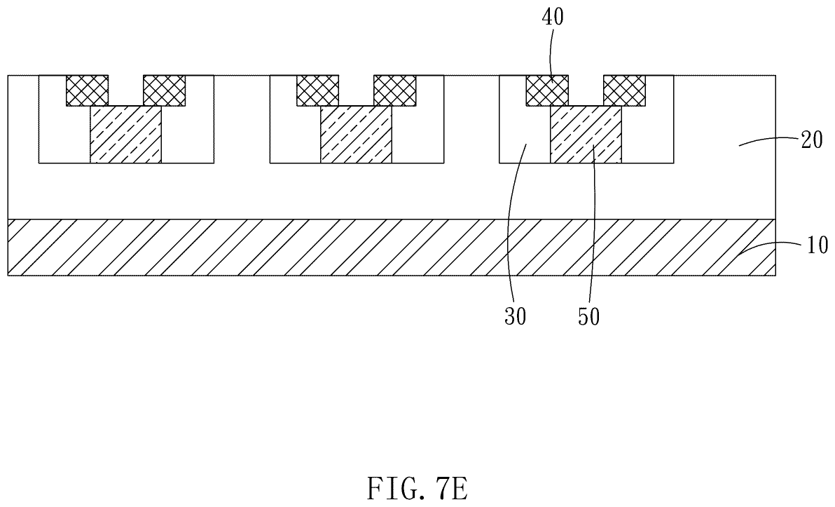

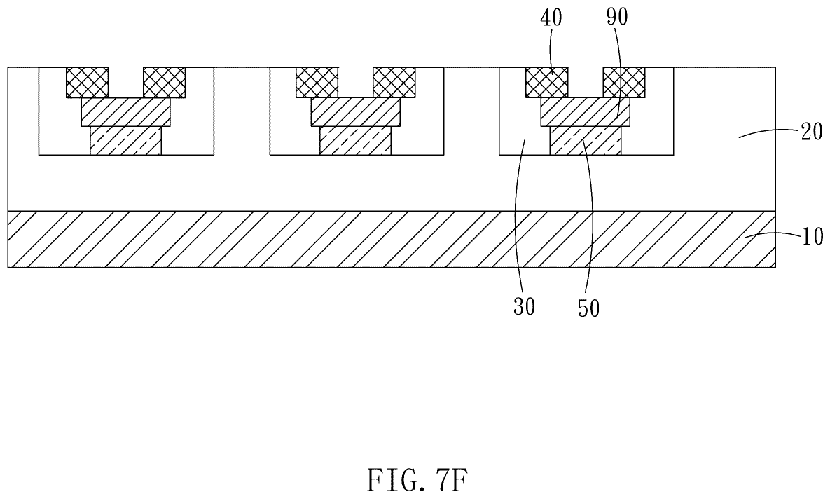

Step S11: forming the epitaxial layer 20 on the substrate 10. As shown in FIG. 7A, the epitaxial layer 20 is formed on the substrate 10 by vapor phase epitaxy (VPE) or metal-organic chemical vapor deposition (MOCVD).

Step S12: forming the plurality of well regions 30 in the epitaxial layer 20. As shown in FIG. 7A, a first photoresist layer PR1 with a first pattern is formed on the epitaxial layer 20, and based on the first photoresist layer PR1, the plurality of well regions 30 are formed in the epitaxial layer 20 by ion implantation.

Step S13: forming the plurality of source regions 40 in the plurality of well regions 30. Because the well region 30 needs to encompass the source region 40, the width of the orthogonal projection of the source region 40 on the substrate 10 needs to be less than the width of the orthogonal projection of the well region 30 on the substrate 10. Hence, the photoresist layer for the plurality of source regions 40 is required. As shown in FIG. 7B, based on the first photoresist layer PR1, a second photoresist layer PR2 with a second pattern is formed and is a hard mask. Based on the second photoresist layer PR2, the plurality of source regions 40 are formed in the plurality of well regions 30 by the ion implantation.

Step S14: forming the plurality of body contact regions 50 in the plurality of well regions 30. Because the body contact region 50 needs to be located under the source region 40, the width of the orthogonal projection of the body contact region 50 on the substrate 10 needs to be less than the width of the orthogonal projection of the source region 40 on the substrate 10. Hence, the photoresist layer for the plurality of body contact regions 50 is required.

After the second photoresist layer PR2 is removed, a first auxiliary photoresist layer PRA1 is formed as shown in FIG. 7C. Based on the first auxiliary photoresist layer PRA1, the plurality of body contact regions 50 are formed in the plurality of well regions 30 by the ion implantation. Each body contact region 50 is located under the corresponding source region 40, and each well region 30 encompasses the corresponding body contact region 50.

Step S15: forming the plurality of auxiliary doping source regions 90 in the corresponding body contact regions 50. Specifically, the auxiliary doping source regions 90 are formed between some body contact regions 50 and some source regions 40, while there is not any auxiliary doping source region 90 between other body contact regions 50 and other source regions 40. Because the auxiliary doping source region 90 needs to be located between the body contact region 50 and the source region 40, the width of the orthogonal projection of the auxiliary doping source region 90 on the substrate 10 needs to be less than or equal to the width of the orthogonal projection of the body contact region 50 on the substrate 10. Hence, the photoresist layer for the plurality of auxiliary doping source regions 90 is required.

After the first auxiliary photoresist layer PRA1 is removed, a second auxiliary photoresist layer is formed. Based on the second auxiliary photoresist layer, each auxiliary doping source region 90 is formed under the corresponding source region 40 but on the corresponding body contact region 50 by the ion implantation. As shown in FIG. 7D, each auxiliary doping source region 90 is located between the corresponding body contact region 50 and the corresponding source region 40.

It should be noted that the step S15 precedes the step S14. In other words, the plurality of auxiliary doping source regions 90 are formed first, and then the body contact regions 50 are formed.

Step S16: partially etching the plurality of source regions 40. As shown in FIG. 7E, based on the first auxiliary photoresist layer, some source regions 40 are partially etched by wet etching or inductively coupled plasma reactive-ion etching (ICP-RIE) and the top side of each body contact region 50 is exposed. The semiconductor structure shown in FIG. 7E may serve as the first transistors 1A, 1B and 1C shown in FIG. 2A. As shown in FIG. 7F, based on the second auxiliary photoresist layer, some source regions 40 are partially etched by the wet etching or ICP-RIE and the top side of each auxiliary doping source region 90 is exposed. The semiconductor structure shown in FIG. 7F may serve as the second transistor 2A, 2B and 2C shown in FIG. 2B.

In another embodied aspect, the photomasks for forming the plurality of source regions 40 in the plurality of well regions 30, forming the plurality of body contact regions 50 in the plurality of well regions 30 and forming the plurality of auxiliary doping source regions 90 in the corresponding body contact regions 50 are the same. In other words, the step S13, the step S14 and the step S15 share one photoresist layer.

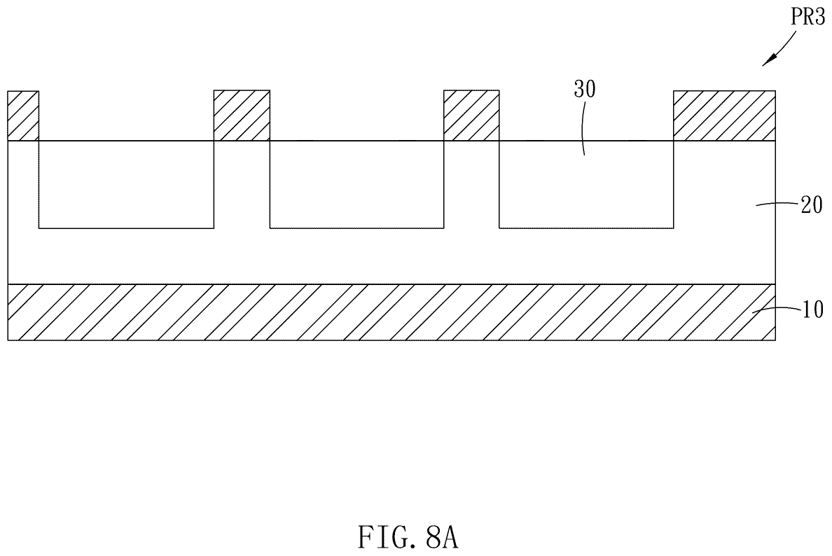

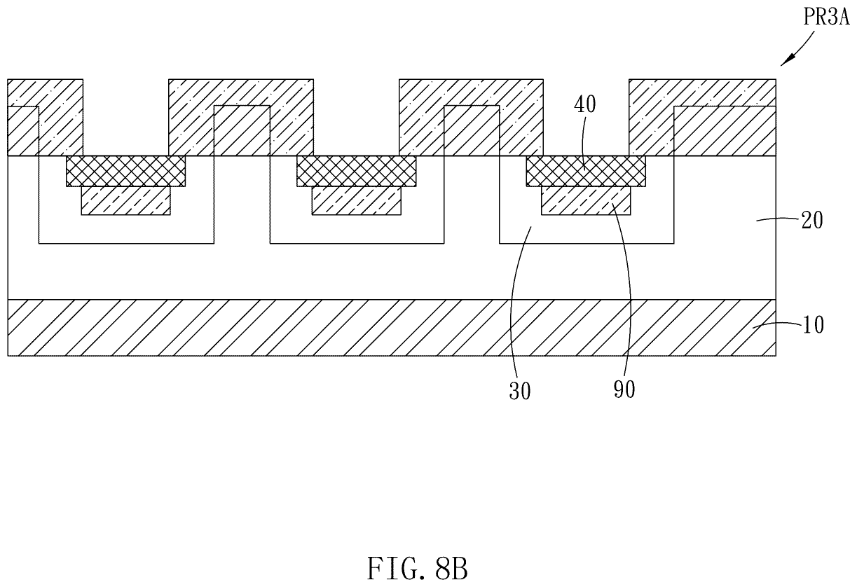

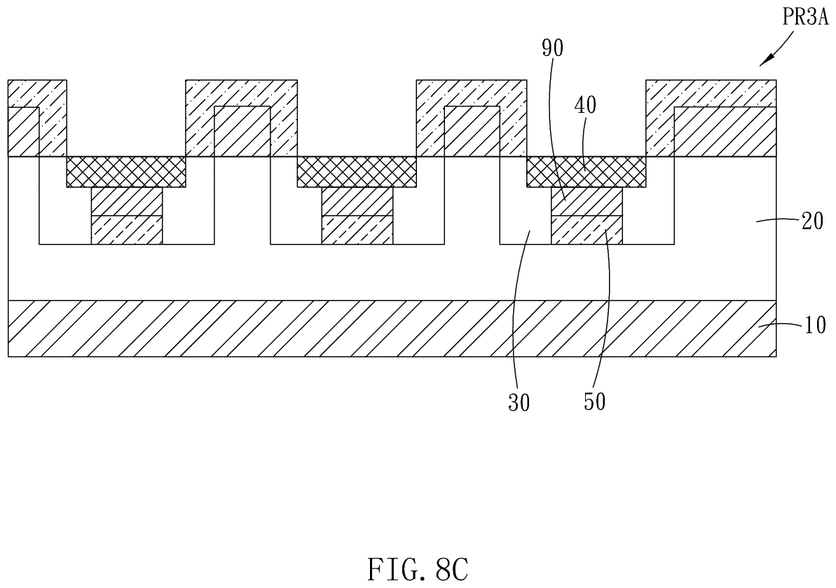

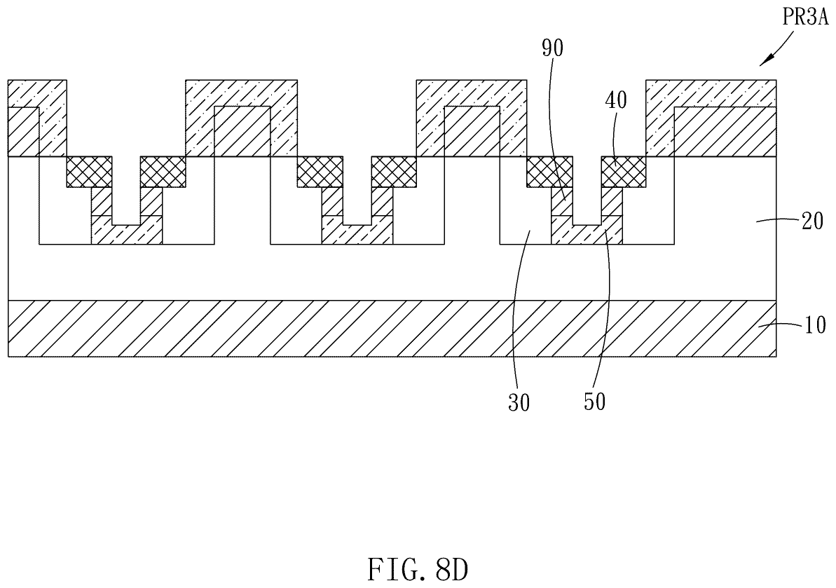

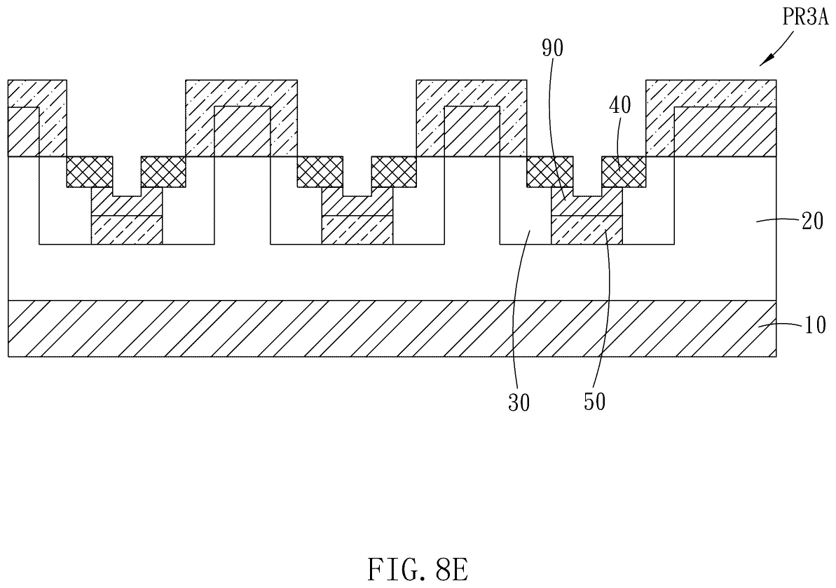

As shown in FIG. 8A, a third photoresist layer PR3 with a third pattern is formed on the epitaxial layer 20. Based on the third photoresist layer PR3, the plurality of well regions 30 are formed in the epitaxial layer 20 by the ion implantation.

Because the well region 30 needs to encompass the source region 40, the third photoresist layer PR3 requires adjusting. As shown in FIG. 8B, a third auxiliary photoresist layer PR3A is formed based on the third photoresist layer PR3 and is the hard mask. Based on the third auxiliary photoresist layer PR3A, the plurality of source regions 40 are formed in the plurality of well regions 30 by the ion implantation.

In one embodied aspect, the plurality of auxiliary doping source regions 90 are formed under the corresponding source regions 40 based on the third auxiliary photoresist layer PR3A. As shown in FIG. 8C, after the auxiliary doping source regions 90 are formed, the plurality of body contact regions 50 are formed under the corresponding auxiliary doping source regions 90 based on the third auxiliary photoresist layer PR3A. Given that the width of the orthogonal projection of the body contact region 50 on the substrate 10 and the width of the orthogonal projection of the auxiliary doping source region 90 on the substrate 10 are less than the width of the orthogonal projection of the source region 40 on the substrate 10, the ion implantation condition corresponding to the body contact region 50 and the ion implantation condition corresponding to the auxiliary doping source region 90 are different from the ion implantation condition corresponding to the source region 40.

In another embodied aspect, the plurality of body contact regions 50 are formed under the corresponding source regions 40 based on the third auxiliary photoresist layer PR3A. After the plurality of body contact regions 50 are formed, the plurality of auxiliary doping source regions 90 are formed on the corresponding body contact regions 50 but under the corresponding source regions 40 based on the third photoresist layer PR3A. Thus, as shown in FIG. 8C, the auxiliary doping source region 90 is disposed between the corresponding source region 40 and the corresponding body contact region 50.

Finally, as shown in FIG. 8D, some source regions 40, some auxiliary doping source regions 90 and some body contact regions 50 are partially etched. The middle part of each source region 40 and the middle part of each auxiliary doping source region 90 are removed to form a first groove, and the first groove exposes the top side of the corresponding body contact region 50. As shown in FIG. 8E, other source regions 40 and other auxiliary doping source regions 90 are partially etched. The middle part of each source region 40 is removed to form a second groove, and the second groove exposes the top side of the corresponding auxiliary doping source region 90. The depth of the first groove is greater than the depth of the second groove.

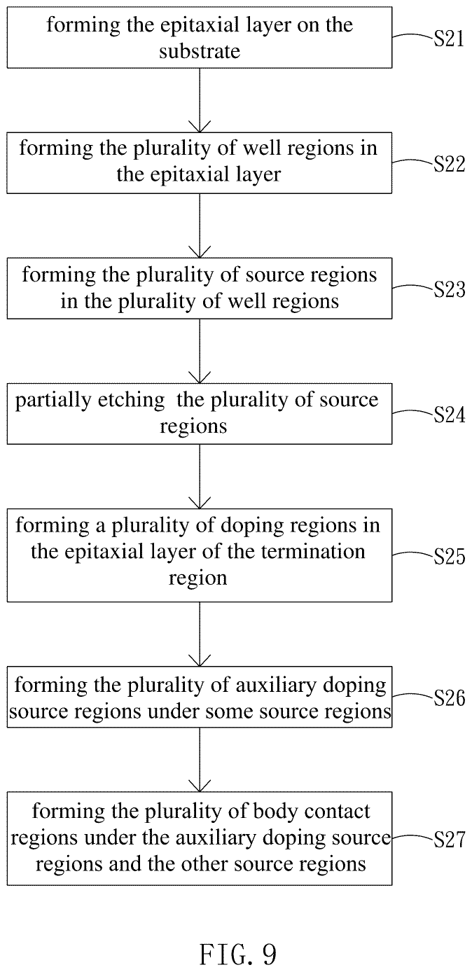

Please refer to FIG. 9, which depicts the flowchart of a manufacturing method of a semiconductor device according to another embodiment. As shown in FIG. 9, the manufacturing method of the semiconductor device includes step S21~step S27. The difference between the manufacturing method of the semiconductor device shown in FIG. 6 and the manufacturing method of the semiconductor device shown in FIG. 9 is: partially etching the plurality of source regions precedes forming the plurality of auxiliary doping source regions in the corresponding body contact regions. The step S21~step S23 shown in FIG. 9 are the same as the step S11~step S13 shown in FIG. 6 and would not be repeated.

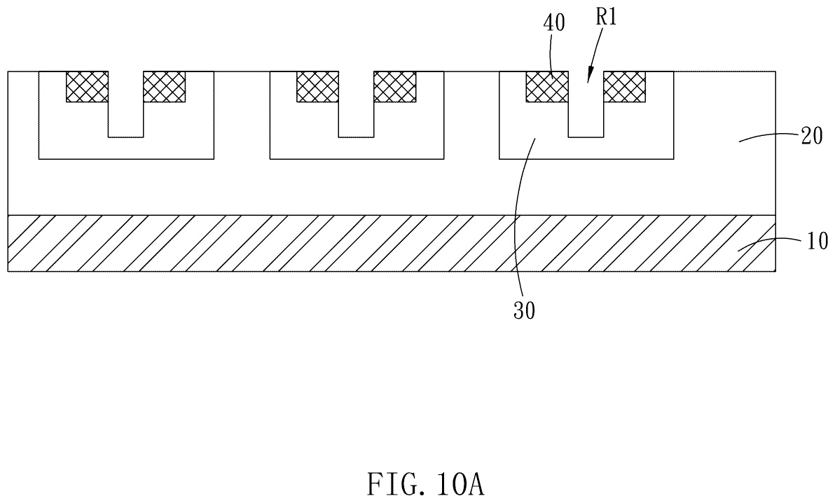

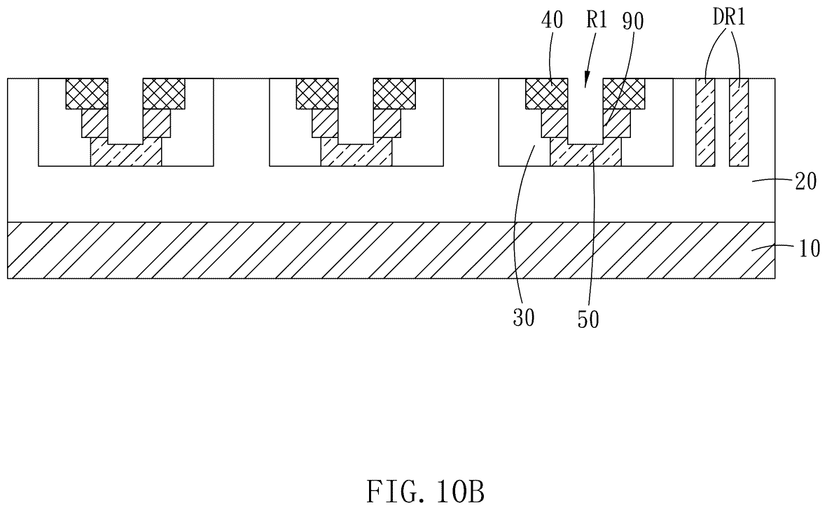

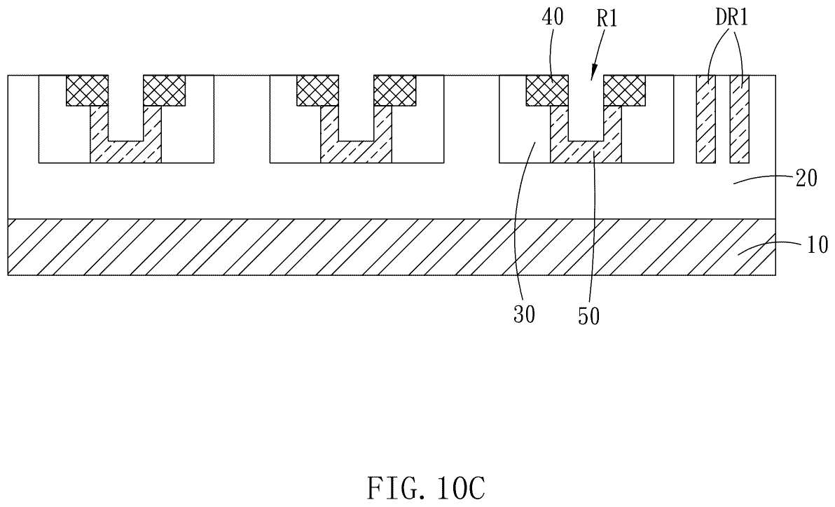

Step S24: partially etching the plurality of source regions 40. In the present embodiment, an auxiliary oxide layer is formed on the epitaxial layer 20, and based on the auxiliary oxide layer, the plurality of source regions 40 are partially etched by the wet etching or ICP-RIE. After the plurality of source regions 40 are partially etched, a plurality of recesses R1 are formed as shown in FIG. 10A.

Step S25: forming a plurality of doping regions DR1 in the epitaxial layer 20 of the termination region TR1. As shown in FIG. 10B and FIG. 10C, the plurality of doping regions DR1 are formed in the epitaxial layer 20 on the termination region TR1 (referring to FIG. 5) by the ion implantation. In addition, the step of forming the plurality of doping regions DR1 can be applied to the manufacturing method of the semiconductor device shown in FIG. 6, and the step of forming the plurality of doping regions DR1 may be performed after the step S14, or the step of forming the plurality of doping regions DR1 and the step S14 may be synchronously performed.

Step S26: forming the plurality of auxiliary doping source regions 90 under some source regions 40. Specifically, some well regions 30 have the auxiliary doping source regions 90, and other well regions 30 does not have any auxiliary doping source region 90. Specifically, each auxiliary doping source region 90 is formed under the corresponding source regions 40 by the ion implantation and extends from the bottom and the sidewall of the corresponding recess R1 to the well region 30.

Step S27: forming the plurality of body contact regions 50 under the auxiliary doping source regions 90 and the other source regions 40. Specifically, some body contact regions 50 are formed under the auxiliary doping source regions 90, while other body contact regions 50 are formed under other source regions 40. As shown in FIG. 10B, each body contact region 50 extends from the sidewall of the corresponding recess R1 to the well region 30; as a result, the auxiliary doping source region 90 is located between the body contact region 50 and the source region 40. As shown in FIG. 10C, each body contact region 50 extends from the bottom and the sidewall of the corresponding recess R1 to the well region 30; as a result, the body contact region 50 is adjacent to the source region 40. It should be noted that the step S27 and the step S25 may be synchronously performed.

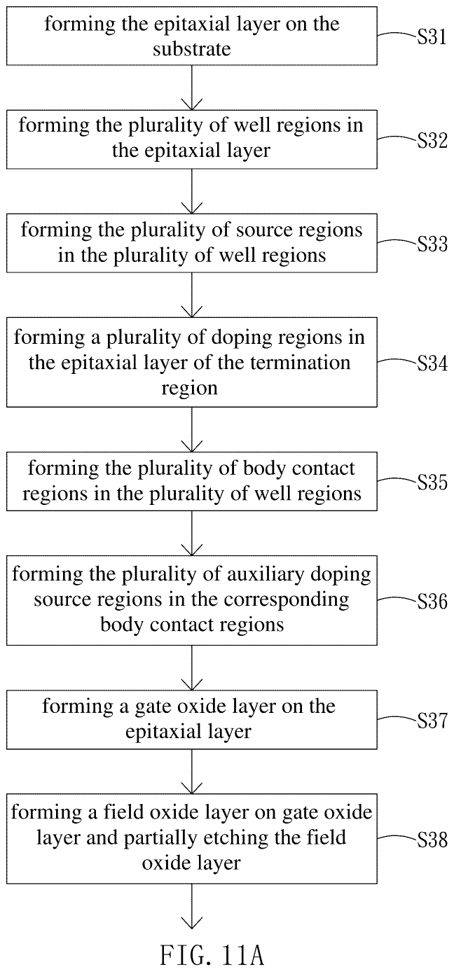

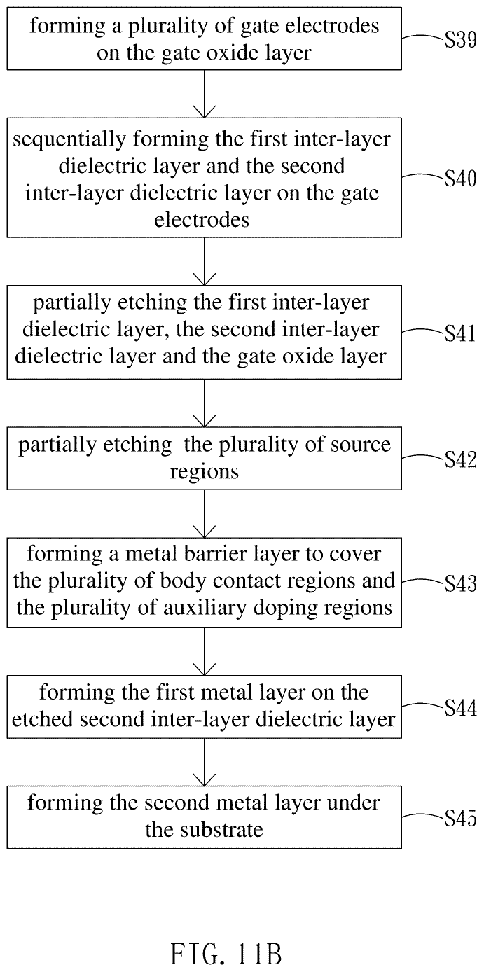

Please refer to FIG. 11A and FIG. 11B, which depict the flowchart of a manufacturing method of a semiconductor device according to yet another embodiment. As shown in FIG. 11A and FIG. 11B, the manufacturing method of the semiconductor device includes steps S31~S45. The step S31 shown in FIG. 11A is the same as the step S11 shown in FIG. 6. The steps S32~S45 would be exemplarily explained by the semiconductor device shown in FIG. 4 to FIG. 5 as follows.

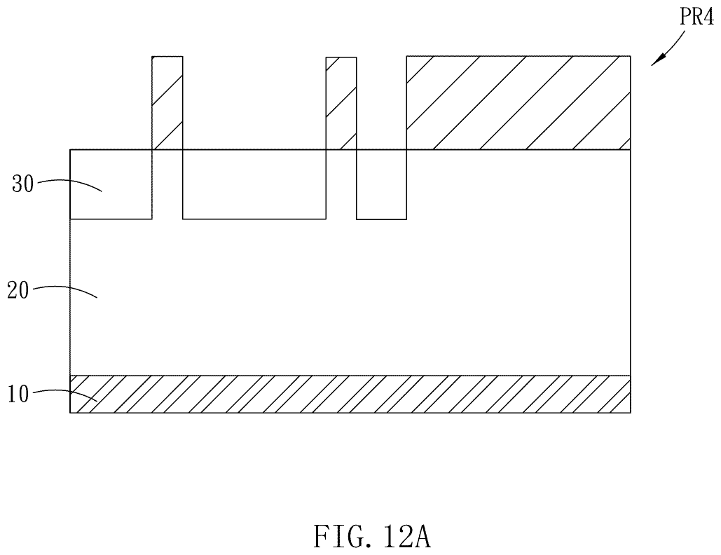

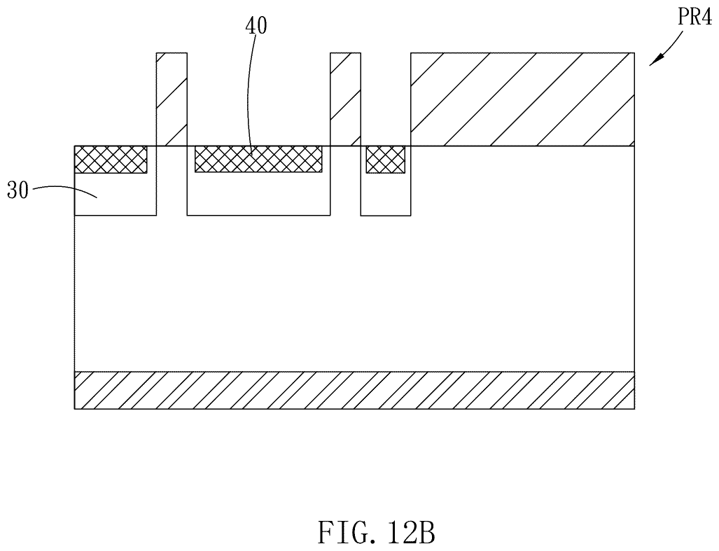

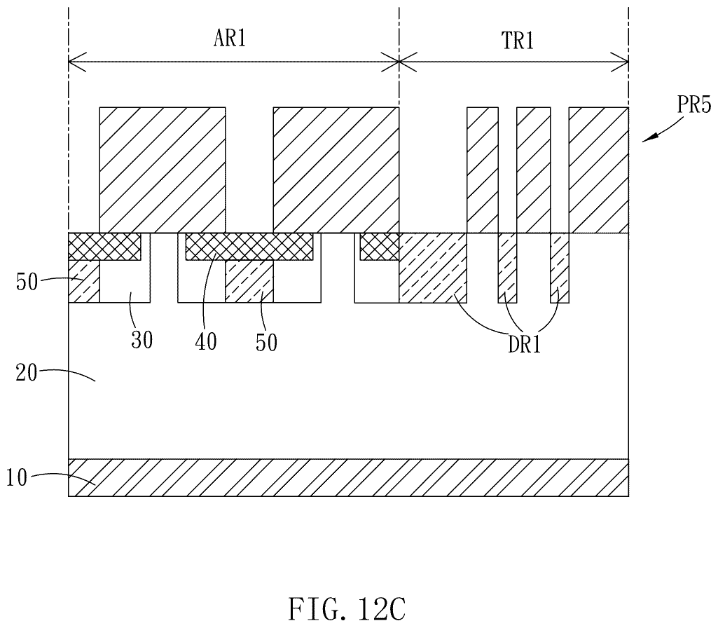

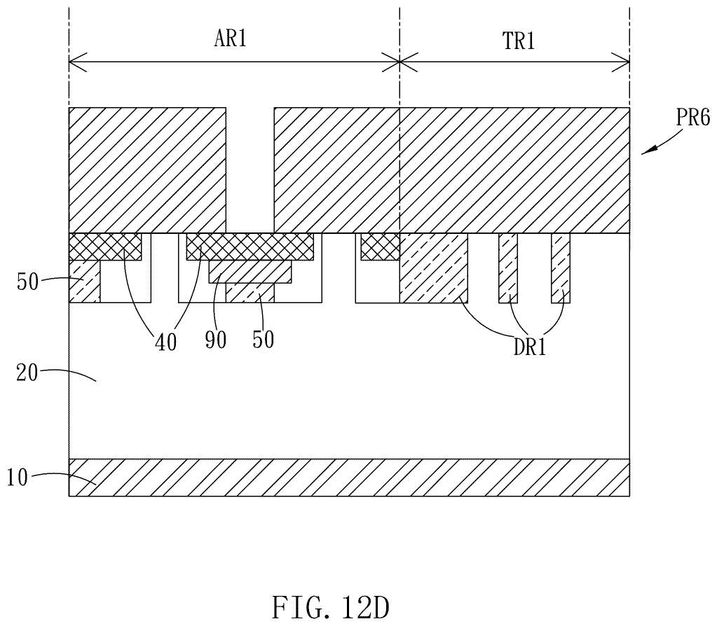

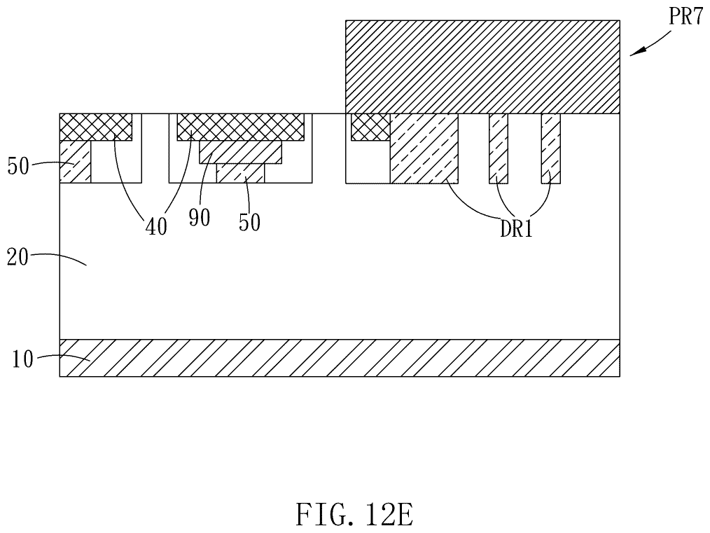

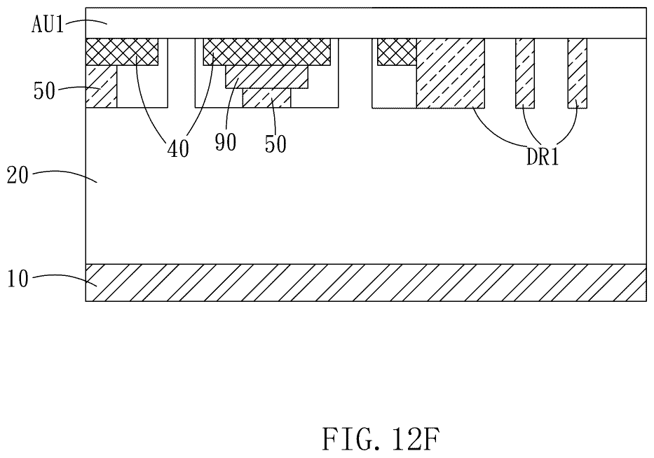

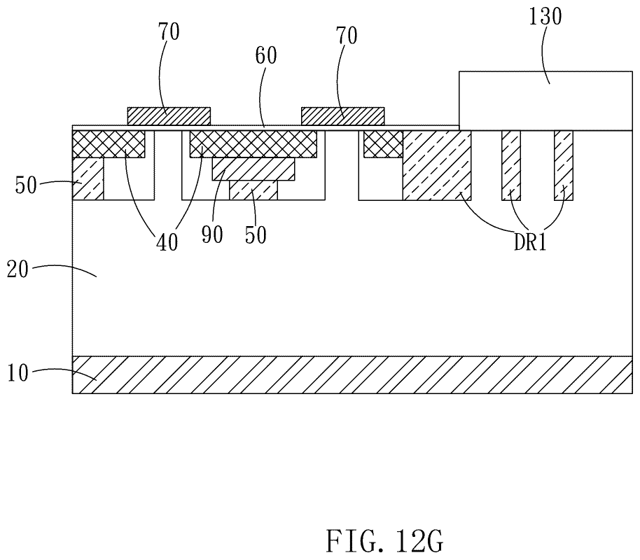

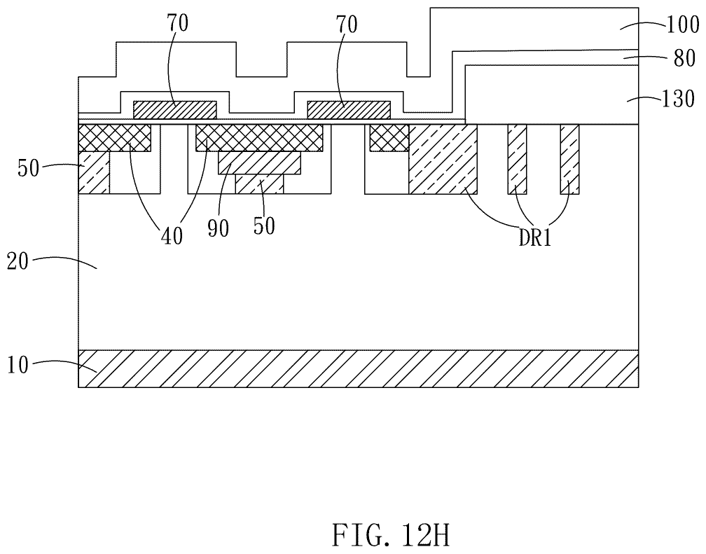

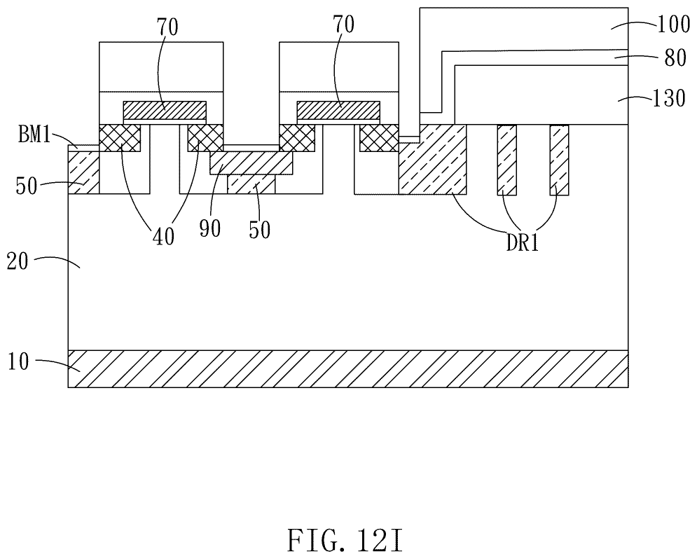

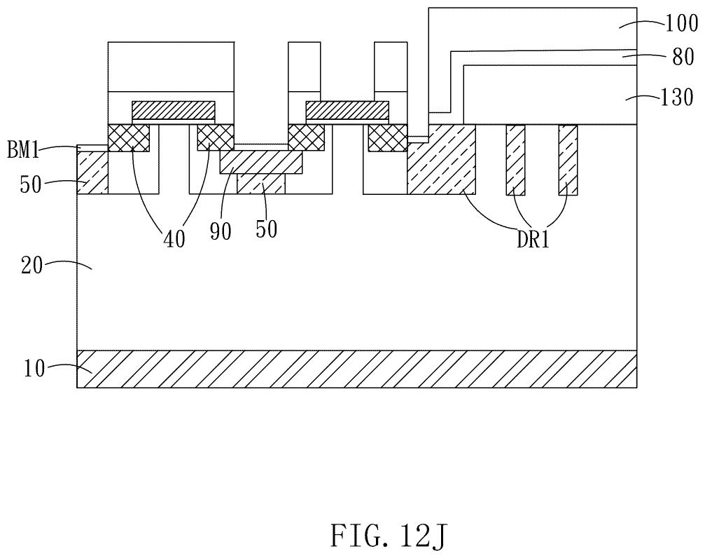

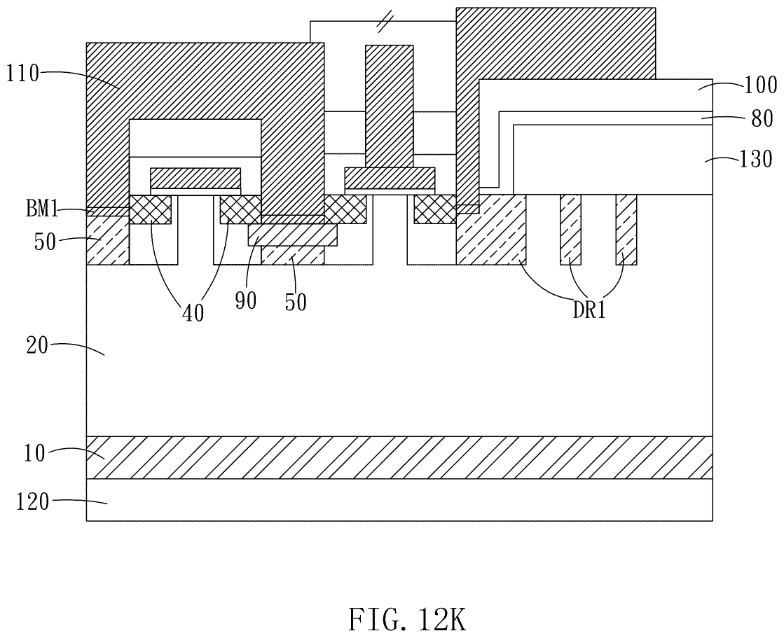

Step S32: forming the plurality of well regions 30 in the epitaxial layer 20. As shown in FIG. 12A, a fourth photoresist layer PR4 with a fourth pattern is formed on the epitaxial layer 20, and based on the fourth photoresist layer PR4, the plurality of well regions 30 are formed in the epitaxial layer 20 by the ion implantation.

Step S33: forming the plurality of source regions 40 in the plurality of well regions 30. Because the well region 30 needs to encompass the source region 40, the fourth photoresist layer PR4 requires adjusting. The fourth photoresist layer PR4 is adjusted. As shown in FIG. 12B, based on the adjusted fourth photoresist layer PR4, the plurality of source regions 40 are formed in the plurality of well regions 30 by the ion implantation.

Step S34: forming the plurality of doping regions DR1 in the epitaxial layer 20 of the termination region TR1.

Step S35: forming the plurality of body contact regions 50 in the plurality of well regions 30. The plurality of body contact regions 50 are situated on the active area AR1.

Because the step S34 and the step S35 are synchronously performed in the present embodiment, the photoresist layer for the plurality of body contact regions 50 and the plurality of doping regions DR1 is required. The fourth photoresist layer PR4 is removed, and a fifth photoresist layer PR5 with a fifth pattern is formed. Based on the fifth photoresist layer PR5, by the ion implantation, the plurality of body contact regions 50 and the plurality of doping regions DR1 are respectively formed in the plurality of well regions 30 and the epitaxial layer 20 of the termination region TR1. Thus, as shown in FIG. 12C, each body contact region 50 and each source region 40 are situated on the active area AR1, while each doping region DR1 is situated on the termination region TR1.

Because the fifth photoresist layer PR5 shields the well region 30 next to the doping region DR1, there is no body contact region 50 in the well region 30 next to the doping region DR1. The well region 30 next to the doping region DR1 merely has the source region 40.

Step S36: forming the plurality of auxiliary doping source regions 90 in the corresponding body contact regions 50. As shown in FIG. 12D, a sixth photoresist layer PR6 with a sixth pattern is formed and exposes one source region 40. Based on the sixth photoresist layer PR6, the auxiliary doping source region 90 is formed in the body contact region 50 by the ion implantation, and the body contact region 50 is located under the exposed source region 40. Afterwards, the sixth photoresist layer PR6 is removed. Although FIG. 12D merely illustrates that one auxiliary doping source region 90 is formed, the auxiliary doping source region 90 may be formed in plural, and forming the plurality of the auxiliary doping source regions 90 is the same as forming one auxiliary doping source region 90 and would not be repeated.

As shown in FIG. 12E, a seventh photoresist layer PR7 is formed. The seventh photoresist layer PR7 exposes the plurality of source regions 40 and covers the plurality of doping regions DR1, and an annealing process is performed on the epitaxial layer 20. Afterwards, the seventh photoresist layer PR7 is removed. As shown in FIG. 12F, the epitaxial layer 20 on the active area AR1 is oxidized by thermal oxidation, and a temporary photoresist layer AU1 is subsequently formed after the epitaxial layer 20 is oxidized. For example, the temporary photoresist layer AU1 is a carbon cap film. After the temporary photoresist layer AU1 is formed, the annealing process is performed on the temporary photoresist layer AU1.

Step S37: forming the gate oxide layer 60 on the epitaxial layer 20. As shown in FIG. 12G, after the temporary photoresist layer AU1 is subsequently removed, the gate oxide layer 60 is situated on the epitaxial layer 20 on the active area AR1. The method of forming the gate oxide layer 60 is chemical vapor deposition (CVD), molecular beam epitaxy (MBE), atomic layer deposition (ALD) or sputtering.

Step S38: forming the field oxide layer 130 on the gate oxide layer 60 and partially etching the field oxide layer 130. As shown in FIG. 12G, the field oxide layer 130 is situated on the epitaxial layer 20 on the termination area TR1. The method of forming the field oxide layer 130 is the same as the method of forming the gate oxide layer 60 and would not be repeated.

In the present embodiment, forming the gate oxide layer 60 and forming the field oxide layer 130 may be synchronous. When a second oxide layer is formed to cover the epitaxial layer 20 on the active area AR1 and the termination area TR1, the thickness of the second oxide layer on the active area AR1 is the same as the thickness of the second oxide layer on the termination area TR1. Afterwards, the second oxide layer on the active area AR1 is partially etched, and the thickness of the second oxide layer on the active area AR1 is less than the thickness of the second oxide layer on the termination area TR1. The second oxide layer on the active area AR1 serves as the gate oxide layer 60, while the second oxide layer on the termination area TR1 serves as the field oxide layer 130.

Step S39: forming the plurality of gate electrodes 70 on the gate oxide layer 60. By a metal mask with a plurality of openings, the plurality of gate electrodes 70 are formed as shown in FIG. 12G. The method of forming the plurality of gate electrodes 70 may be CVD, thermal evaporation or sputtering.

Step S40: sequentially forming the first inter-layer dielectric layer 80 and the second inter-layer dielectric layer 100 on the gate electrodes 70. As shown in FIG. 12H, the first inter-layer dielectric layer 80 is formed on the gate electrodes 70, and the second inter-layer dielectric layer 100 is formed on the first inter-layer dielectric layer 80. The method of forming the first inter-layer dielectric layer 80 and the second inter-layer dielectric layer 100 is the same as the method of forming the gate oxide layer 60 and would not be repeated.

Step S41: partially etching the first inter-layer dielectric layer 80, the second inter-layer dielectric layer 100 and the gate oxide layer 60.

Step S42: partially etching the plurality of source regions 40.

In the present embodiment, the step S41 and the step S42 are synchronously performed. An auxiliary dielectric layer with a plurality of through hole is formed on the second inter-layer dielectric layer 100, and based on the auxiliary dielectric layer, the first inter-layer dielectric layer 80, the second inter-layer dielectric layer 100, the gate oxide layer 60 and the plurality of source regions 40 are partially etched. After the first inter-layer dielectric layer 80, the second inter-layer dielectric layer 100, the gate oxide layer 60 and the plurality of source regions 40 are partially etched, the top surface of each body contact region 50 and the top surface of each auxiliary doping source region 90 are exposed. As shown in FIG. 12I, each source region 40 is transformed into two corresponding source regions 40. The side surface of each corresponding source region 40, the top surface of the body contact region 50, the top surface of the auxiliary doping source region 90, and the top surface of the doping region DR1 are exposed, and source contact regions are formed.

Step S43: forming a metal barrier layer BM1 to cover the plurality of body contact regions 50 and the plurality of auxiliary doping regions 90. As shown on FIG. 12I, the metal barrier layer BM1 is formed to cover the body contact region 50 and the auxiliary doping source region 90 and the doping region DR1. The method of forming the metal barrier layer BM1 may be CVD, thermal evaporation or sputtering. After the metal barrier layer BM1 is formed, the first inter-layer dielectric layer 80 and the second inter-layer dielectric layer 100 are partially etched to expose the gate electrode 70 as shown in FIG. 12J, and a gate contact region is formed.

Step S44: forming the first metal layer 110 on the etched second inter-layer dielectric layer 100. As shown in FIG. 12K, the first metal layer 110 is formed on the etched second inter-layer dielectric layer 100 to contact the gate electrode 70 and the metal barrier layer BM1, and the method of forming the first metal layer 110 is the same as the method of forming the metal barrier layer BM1 and would not be repeated.

Step S45: forming the second metal layer 120 under the substrate 10. As shown in FIG. 12K, the second metal layer 120 is formed under the substrate 10 and serves as a drain electrode. The method of forming the second metal layer 120 is the same as the method of forming the metal barrier layer BM1 and would not be repeated.

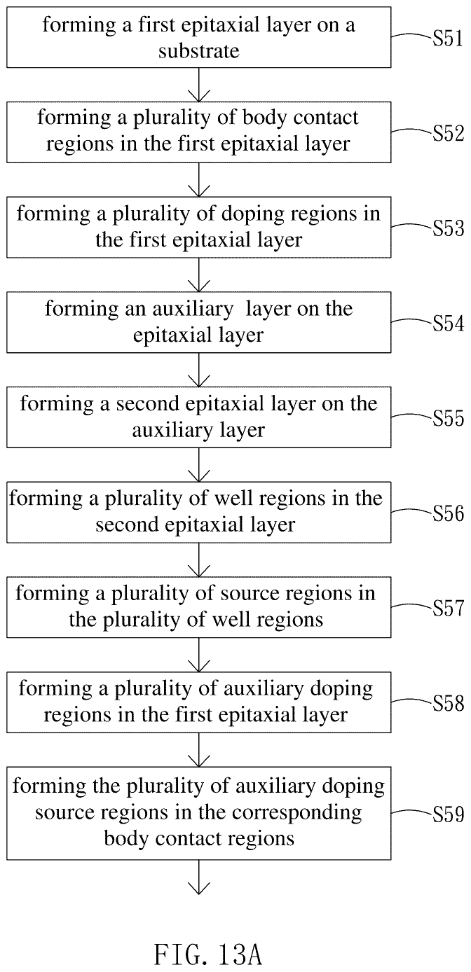

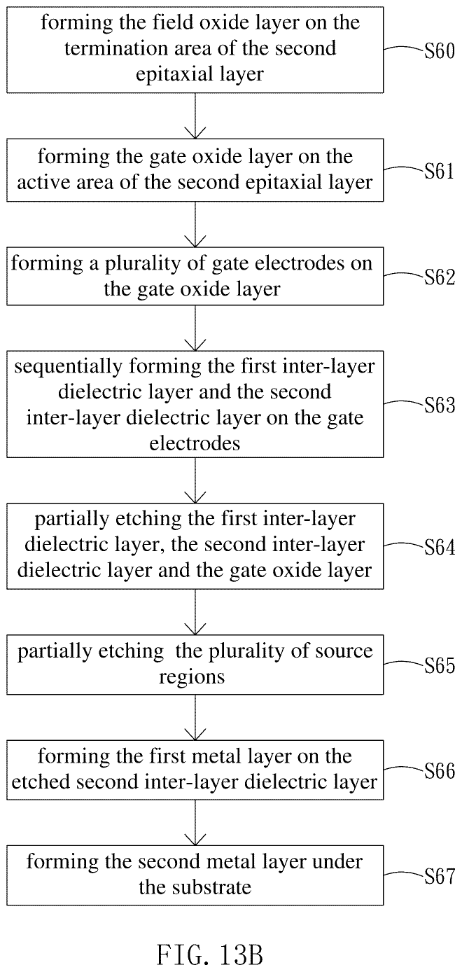

Please refer to FIG. 13A and FIG. 13B, which depict the flowchart of a manufacturing method of a semiconductor device according to still another embodiment. As show in FIG. 13A and FIG. 13B, the manufacturing method of the semiconductor device includes step S51~S67. The steps S51~S67 would be exemplarily explained by the semiconductor device shown in FIG. 4 to FIG. 5 as follows.

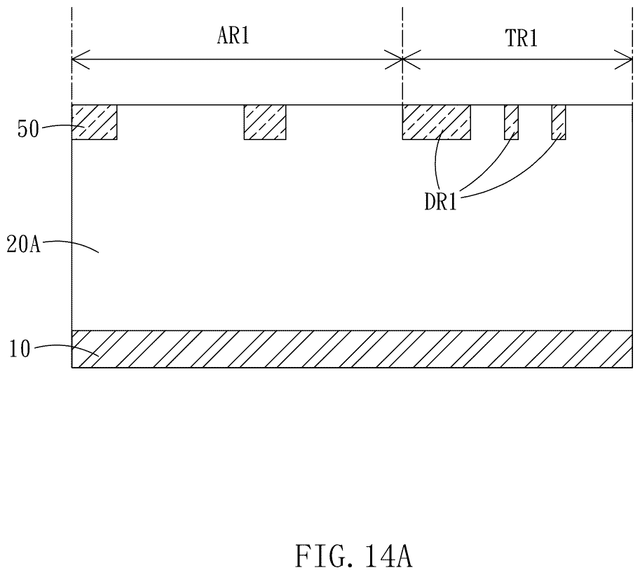

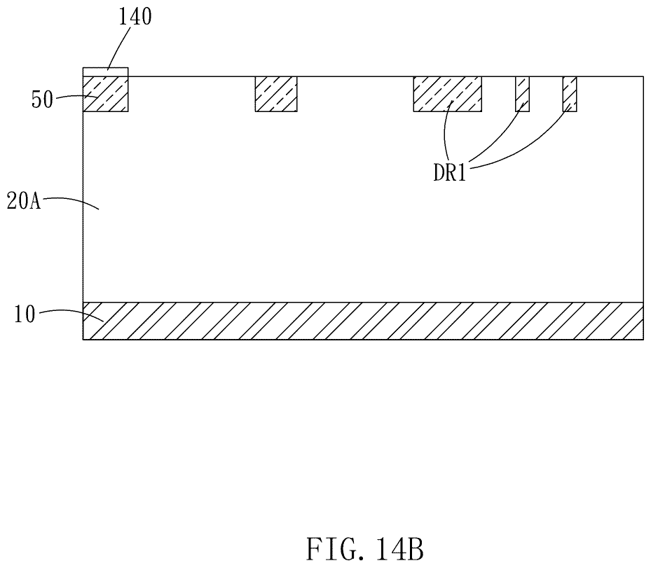

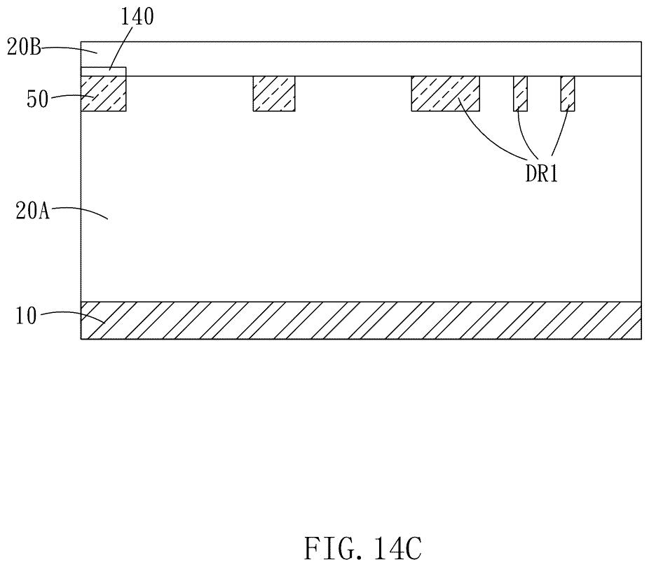

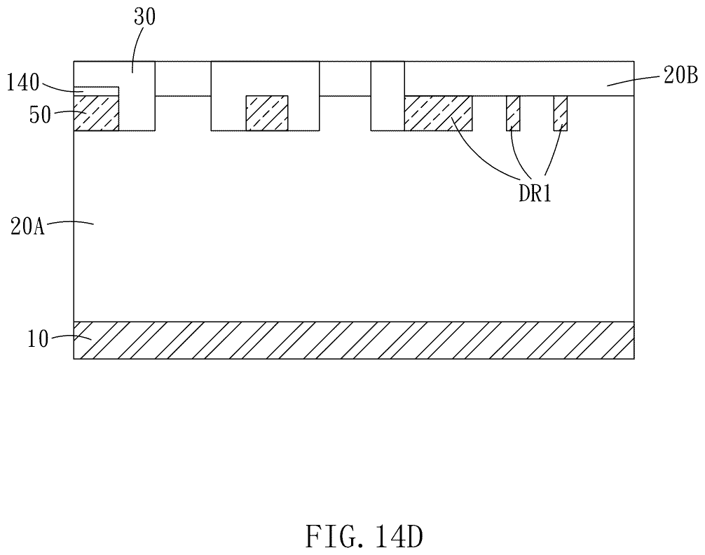

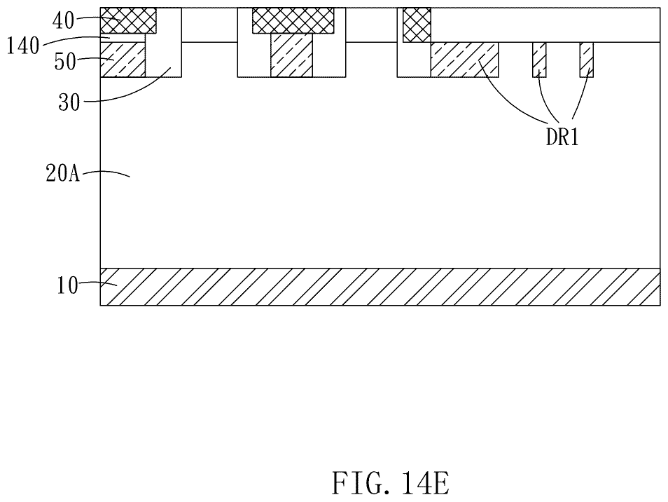

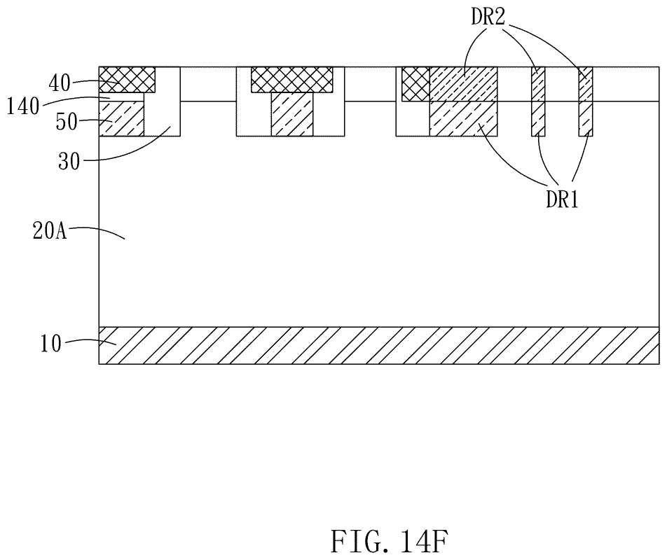

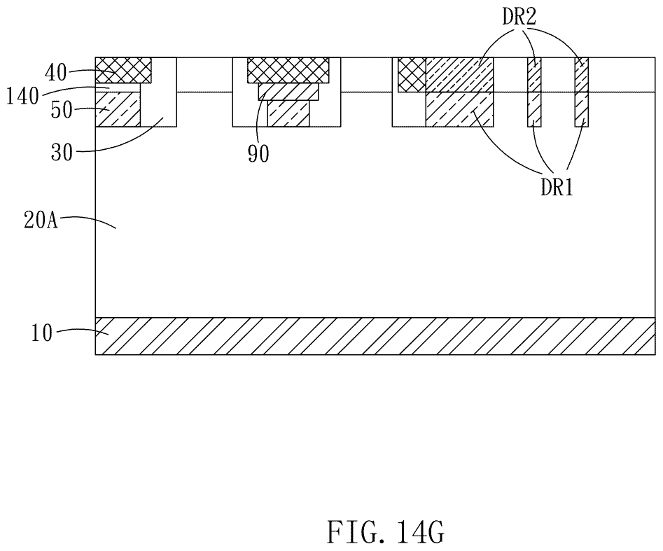

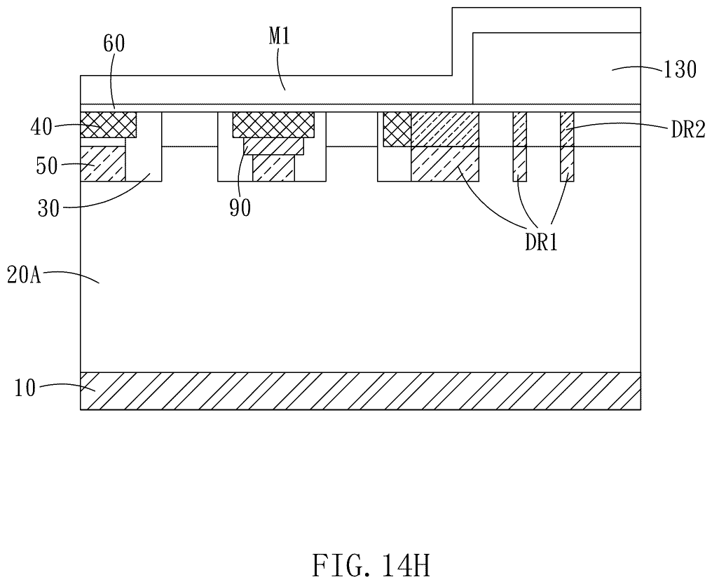

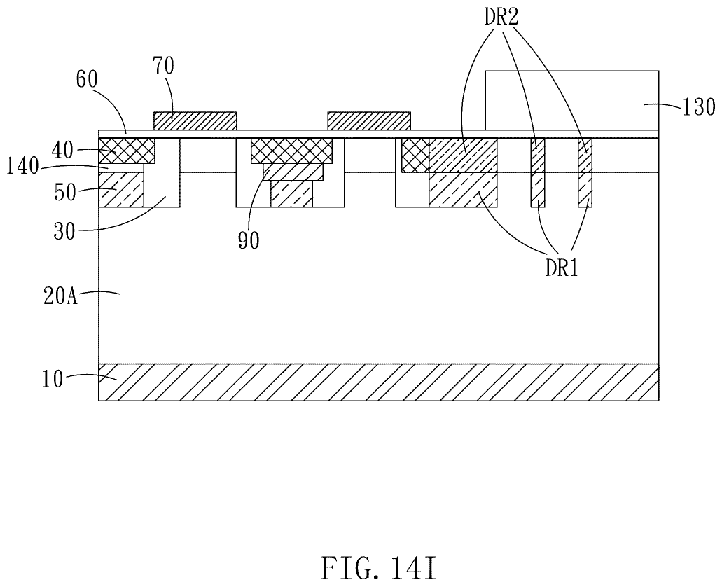

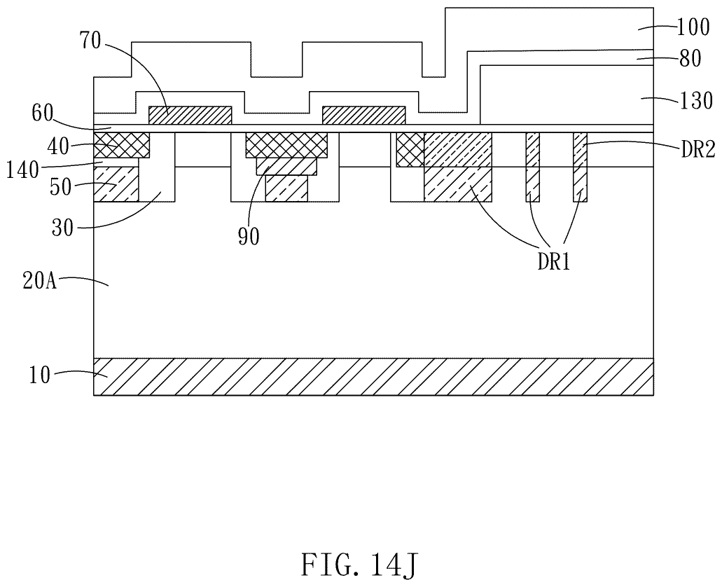

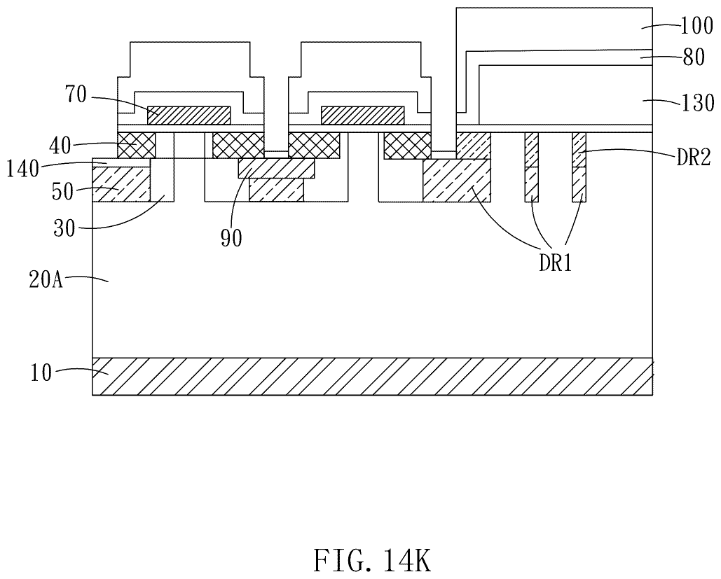

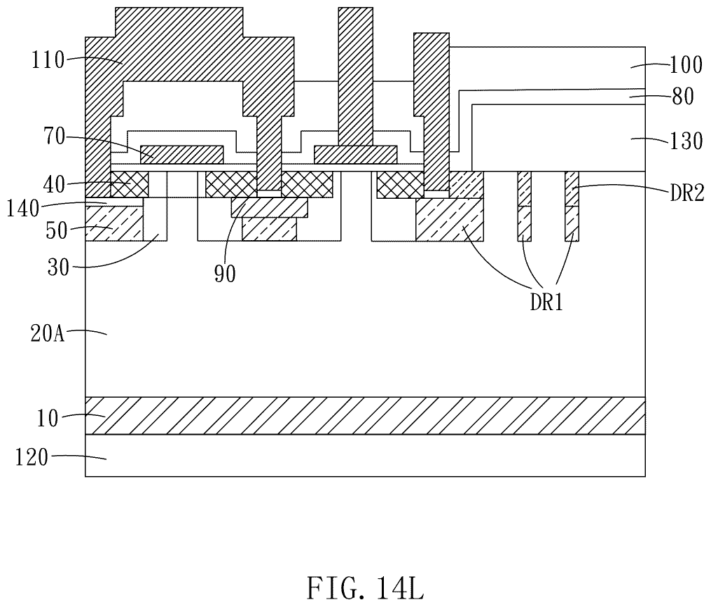

Step S51: forming a first epitaxial layer 20A on the substrate 10. As shown in FIG. 14A, the first epitaxial layer 20A is formed on the substrate 10, and the method of forming the first epitaxial layer 20A is the same as the method of forming the epitaxial layer 20 and would not be repeated. The materials of the first epitaxial layer 20A may be SiC for example.

Step S52: forming a plurality of body contact regions 50 in the first epitaxial layer 20A. As shown FIG. 14A, the plurality of body contact regions 50 are located on the active area AR1. Specifically, each body contact region 50 extends from the surface of the first epitaxial layer 20A and stops in the first epitaxial layer 20A.

Step S53: forming a plurality of doping regions DR1 in the first epitaxial layer 20. As shown in FIG. 14A, the plurality of doping regions DR1 are situated on the termination region TR1 of the first epitaxial layer 20. Specifically, each doping region DR1 extends from the surface of the first epitaxial layer 20A and stops in the first epitaxial layer 20A. In the present embodiment, the step S52 and the step S53 are synchronously performed by the ion implantation.

Step S54: forming an auxiliary layer 140 on the first epitaxial layer 20A. As shown in FIG. 14B, the auxiliary layer 140 is formed to cover each body contact region 50 and the doping region DR1. For example, the material of the auxiliary layer 140 may include silicide. The method of forming the auxiliary layer 140 may be CVD, thermal evaporation or sputtering. During the formation of the auxiliary layer 140, Nickel (Ni) or Titanium (Ti) or Tungsten (W) may be added. After the auxiliary layer 140 is formed, the annealing process at 900° C. to 1000° C. is performed to heat the auxiliary layer 140.

Step S55: forming a second epitaxial layer 20B on the auxiliary layer 140. As shown in FIG. 14C, the second epitaxial layer 20B is formed to cover the auxiliary layer 140, the first epitaxial layer 20A and the doping regions DR1. The method of forming the second epitaxial layer 20B is the same as the method of forming the epitaxial layer 20 and would not be repeated, and the materials of the second epitaxial layer 20B are the same as the materials of the first epitaxial layer 20A and would not be repeated.

Step S56: forming a plurality of well regions 30 in the second epitaxial layer 20B. As shown in FIG. 14D, based on two body contact regions 50, two well regions 30 are formed by the ion implantation. Two well regions 30 extend from the surface of the second epitaxial layer 20B and stop in the first epitaxial layer 20A, and in other words, two well regions 30 respectively encompass two body contact regions 50. In addition, there is one well region 30 formed next to the doping region DR1.

Step S57: forming a plurality of source regions 40 in the plurality of well regions 30. As shown in FIG. 14E, two source regions 40 are formed to cover one part of the auxiliary layer 140 by the ion implantation, and in other words, two source regions 40 are located on the auxiliary layer 140. Because the step S55 precedes the step S57, two source regions 40 are located on two body contact regions 50. In addition, there is one source region 40 formed in the well region 30 next to the doping region DR1.

Step S58: forming a plurality of auxiliary doping regions DR2 in the second epitaxial layer 20B. As shown in FIG. 14F, each auxiliary doping region DR2 is situated on the termination region TR1 of the second epitaxial layer 20B. Specifically, each auxiliary doping region DR2 extends from the surface of the second epitaxial layer 20B and stops in the second epitaxial layer 20B, and the type of each auxiliary doping region DR2 is the second type conductivity. Because the step S53 precedes the step S58, each auxiliary doping region DR2 is located on the corresponding doping region DR1.

Step S59: forming the plurality of auxiliary doping source regions 90 in the corresponding body contact regions 50. As shown in FIG. 14G, the auxiliary doping source region 90 is formed in the body contact region 50 by the ion implantation. The auxiliary doping source region 90 extends from the edge of the source region 40 to the edge of the body contact region 50; in other words, the auxiliary doping source region 90 is disposed between the source region 40 and the body contact region 50 and covers one part of the auxiliary layer 140. Although FIG. 14G merely illustrates that one auxiliary doping source region 90 is formed, the auxiliary doping source region 90 may be formed in plural, and forming the plurality of the auxiliary doping source regions 90 is the same as forming one auxiliary doping source region 90 and would not be repeated.

Step S60: forming the field oxide layer 130 on the termination area TR1 of the second epitaxial layer 20B.

Step S61: forming the gate oxide layer 60 on the active area AR1 of the second epitaxial layer 20B.

In the present embodiment, the step S60 and the step S61 are separately performed. Specifically, the field oxide layer 130 is formed to cover the second epitaxial layer 20B on the active area AR1 and the termination area TR1, the field oxide layer 130 is partially etched, and the field oxide layer 130 on the termination area TR1 remains as shown in FIG. 14H. Afterwards, the gate oxide layer 60 is formed on the active area AR1 of the second epitaxial layer 20B.

Step S62: forming the plurality of gate electrodes 70 on the gate oxide layer 60. As shown in FIG. 14H, an auxiliary metal layer M1 is formed on the gate oxide layer 60 by CVD, thermal evaporation or sputtering. As shown in FIG. 14I, the auxiliary metal layer M1 is partially etched, and the plurality of gate electrodes 70 are formed.

Step S63: sequentially forming the first inter-layer dielectric layer 80 and the second inter-layer dielectric layer 100 on the gate electrodes 70. As shown in FIG. 14J, the first inter-layer dielectric layer 80 is formed on the gate electrodes 70 to cover the gate electrodes 70, the gate oxide layer 60 and the field oxide layer 130, and the second inter-layer dielectric layer 100 is formed on the first inter-layer dielectric layer 80.

Step S64: partially etching the first inter-layer dielectric layer 80, the second inter-layer dielectric layer 100 and the gate oxide layer 60.

Step S65: partially etching the plurality of source regions 40.

In the present embodiment, the step S64 and the step S65 are synchronously performed. The auxiliary dielectric layer with a plurality of through hole is formed on the second inter-layer dielectric layer 100, and based on the auxiliary dielectric layer, the first inter-layer dielectric layer 80, the second inter-layer dielectric layer 100, the gate oxide layer 60 and the plurality of source regions 40 are partially etched. After the first inter-layer dielectric layer 80, the second inter-layer dielectric layer 100, the gate oxide layer 60 and the plurality of source regions 40 are partially etched, the auxiliary layer 140 is exposed. As shown in FIG. 14K, each source region 40 is transformed into two corresponding source regions 40. The side surface of each corresponding source region 40 is exposed, and the source contact regions are formed. After the source contact regions are formed, the first inter-layer dielectric layer 80 and the second inter-layer dielectric layer 100 are partially etched to expose the gate electrode 70 as shown in FIG. 14L, and the gate contact region is formed.

Step S66: forming the first metal layer 110 on the etched second inter-layer dielectric layer 100. As shown in FIG. 14L, the first metal layer 110 is formed on the etched second inter-layer dielectric layer 100 to contact the gate electrode 70 and the auxiliary layer 140.

Step S67: forming the second metal layer 120 under the substrate 10. As shown in FIG. 14L, the second metal layer 120 is formed under the substrate 10 and serves as the drain electrode.

In view of the above description, in the transistor, the semiconductor device and the manufacturing method of the semiconductor device provided by the present disclosure, the body contact region is located underneath the two corresponding source regions and has at least one side without contacting the source region. In other words, each source region is located on the body contact region and has at least one side without contacting the body contact region. Hence, the semiconductor device and the manufacturing method of the semiconductor device provided by the present disclosure can reduce the lateral spreading current of the transistor and shortening the channel of the transistor.

What is claimed is:

1. A transistor comprising:
a substrate;
an epitaxial layer disposed on the substrate;
two well regions separately disposed in the epitaxial layer;
two source regions respectively disposed in the two well regions; and
a body contact region disposed in each well region, wherein the body contact region is located under the two source regions.

2. The transistor according to claim 1, wherein the transistor is a MOSFET, a IGBT or a SJ-MOSFET.

3. The transistor according to claim 1, wherein the transistor is a planar type MOSFET, a trench type MOSFET, or a stripe pattern MOSFET and a cell pattern MOSFET.

4. The transistor according to claim 1, wherein the body contact region has at least one side without contacting the source region.

5. The transistor according to claim 1, wherein the two source regions encompass the body contact region.

6. The transistor according to claim 1, further comprising:
a gate oxide layer disposed on the epitaxial layer;
a gate electrode disposed on the gate oxide layer;
a first inter-layer dielectric layer disposed on the gate electrode and encompassing the first gate electrode; and
a second inter-layer dielectric layer disposed on the first inter-layer dielectric layer.

7. The transistor according to claim 1, further comprising:
a first metal layer disposed on the second inter-layer dielectric layer; and
a second metal layer disposed under the substrate.

8. A transistor comprising:
a substrate;
an epitaxial layer disposed on the substrate;
two well regions separately disposed in the epitaxial layer;
two source regions respectively disposed in the two well regions;
a body contact region disposed in each well region, wherein the body contact region is located underneath the two source regions; and
an auxiliary doping source region disposed between the two source regions and the body contact region, wherein a doping concentration of the auxiliary doping region is greater than a doping concentration of each of the two source regions.

9. The transistor according to claim 8, wherein the transistor is a MOSFET, a IGBT or a SJ-MOSFET.

10. The transistor according to claim 8, wherein the transistor is a planar type MOSFET, a trench type MOSFET, or a stripe pattern MOSFET and a cell pattern MOSFET.

11. The transistor according to claim 8, wherein the body contact region has at least one side without contacting the source region.

12. The transistor according to claim 8, wherein the two source regions encompass the body contact region.

13. The transistor according to claim 8, wherein the two source regions encompass the auxiliary doping source region, and the auxiliary doping source region is disposed on the body contact region.

14. The transistor according to claim 8, further comprising:
a gate oxide layer disposed on the epitaxial layer;
a gate electrode disposed on the gate oxide layer;
a first inter-layer dielectric layer disposed on the gate electrode and encompassing the first gate electrode; and
a second inter-layer dielectric layer disposed on the first inter-layer dielectric layer.

15. The transistor according to claim 8, further comprising:
a first metal layer disposed on the second inter-layer dielectric layer; and
a second metal layer disposed under the substrate.

16. A semiconductor device comprising:
a substrate with a plurality of first zones and a plurality of second zones;
an epitaxial layer disposed on the substrate;
a plurality of first transistors disposed on the plurality of first zones of the epitaxial layer and each of which comprises:
two first well regions separately disposed in the first zone of the epitaxial layer;
two first source regions respectively disposed in the two first well regions; and
a first body contact region disposed in each first well region, wherein the first body contact region is located under the two first source regions;
a plurality of second transistors disposed on the plurality of second zones of the epitaxial layer and each of which comprises:
two second well regions separately disposed in the second zone of the epitaxial layer;
two second source regions respectively disposed in the two second well regions;
a second body contact region disposed in each second well region, wherein the second body contact region is located under the two second source regions; and
an auxiliary doping source region disposed between the two second source regions and the second body contact region, wherein a doping concentration of the auxiliary doping region is greater than a doping concentration of each of the two second source regions;
wherein, by arranging the plurality of first transistors and the plurality of second transistors alternately, four sides of the first body contact region are surrounded by the two first source regions and the two auxiliary doping source regions.

17. The semiconductor device according to claim 16, wherein the semiconductor device has an active area and a termination area surrounding the active area, and the plurality of first transistors and the plurality of second transistors are disposed on the active area.

18. A manufacturing method of a semiconductor device comprising:
forming an epitaxial layer on a substrate;
forming a plurality of well regions in the epitaxial layer;
forming a plurality of source regions in the plurality of well regions;
forming a plurality of body contact regions in the plurality of well regions;
forming a plurality of auxiliary doping source regions in the corresponding body contact regions, wherein a doping concentration of the auxiliary doping region is greater than a doping concentration of each of the plurality of source regions; and
partially etching the plurality of source regions;
wherein each body contact region is located underneath the two source regions, and each auxiliary doping source region is disposed between the corresponding body contact region and the two corresponding source regions.

19. The manufacturing method of the semiconductor device according to claim 18, wherein partially etching the plurality of source regions comprising:
forming a photoresist layer on the epitaxial layer, wherein the photoresist layer exposes the plurality of source regions;
annealing the epitaxial layer;
oxidizing the epitaxial layer;
forming a temporary photoresist layer; and
partially etching the plurality of source regions.

20. The manufacturing method of the semiconductor device according to claim 18, wherein partially etching the plurality of source regions precedes forming the plurality of auxiliary doping source regions in the corresponding body contact regions; after partially etching the plurality of source regions, a plurality of recesses are formed, wherein each auxiliary doping source region is located on a bottom of the corresponding recess.

21. The manufacturing method of the semiconductor device according to claim 18, wherein the semiconductor device has an active area and a termination area surrounding the active area, the plurality of well regions, the plurality of source regions, the plurality of body contact regions and the auxiliary doping source region are disposed on the active area, and the manufacturing method of the semiconductor device further comprising:
forming a plurality of doping regions in the epitaxial layer of the termination region, wherein forming the plurality of doping regions in the epitaxial layer of the termination region is synchronous with or asynchronous with forming the plurality of body contact regions in the plurality of well regions.

22. The manufacturing method of the semiconductor device according to claim 18, wherein photomasks for forming the plurality of source regions in the plurality of well regions, forming the plurality of body contact regions in the plurality of well regions and forming the plurality of auxiliary doping source regions in the corresponding body contact regions are the same.

23. The manufacturing method of the semiconductor device according to claim 18, further comprising:
forming a gate oxide layer on the epitaxial layer;
forming a plurality of gate electrodes on the gate oxide layer;
sequentially forming a first inter-layer dielectric layer and a second inter-layer dielectric layer on the gate electrodes; and
partially etching the first inter-layer dielectric layer, the second inter-layer dielectric layer and the gate oxide layer.

24. The manufacturing method of the semiconductor device according to claim 23, further comprising:
forming a first metal layer on the etched second inter-layer dielectric layer; and
forming a second metal layer under the substrate.

25. The manufacturing method of the semiconductor device according to claim 23, wherein partially etching the first inter-layer dielectric layer and the second inter-layer dielectric layer is synchronous with partially etching the plurality of source regions, the manufacturing method of the semiconductor device further comprising:
forming a metal barrier layer to cover the plurality of body contact regions and the plurality of auxiliary doping regions.

26. A manufacturing method of a semiconductor device comprising:
forming a first epitaxial layer on a substrate;
forming a plurality of body contact regions in the first epitaxial layer;
forming an auxiliary layer on the first epitaxial layer, wherein the auxiliary layer covers the plurality of body contact regions;
forming a second epitaxial layer on the auxiliary layer;
forming a plurality of well regions in the second epitaxial layer, wherein each well region encompasses the corresponding body contact region;
forming a plurality of source regions in the plurality of well regions, wherein each body contact region is located underneath the corresponding source region;
forming an auxiliary doping source region in the corresponding body contact region, wherein the auxiliary doping source region extends from the corresponding source region to the corresponding body contact region; and
partially etching the plurality of source regions, wherein each of the plurality of body contact regions is located under the corresponding two source regions.

27. The manufacturing method of the semiconductor device according to claim 26, further comprising:
forming a gate oxide layer on the epitaxial layer;
forming a plurality of gate electrodes on the gate oxide layer;
sequentially forming a first inter-layer dielectric layer and a second inter-layer dielectric layer on the gate electrodes; and
partially etching the first inter-layer dielectric layer, the second inter-layer dielectric layer and the gate oxide layer.

28. The manufacturing method of the semiconductor device according to claim 27, further comprising:
forming a first metal layer on the etched second inter-layer dielectric layer; and
forming a second metal layer under the substrate.

29. The manufacturing method of the semiconductor device according to claim 27, wherein partially etching the first inter-layer dielectric layer and the second inter-layer dielectric layer is synchronous with partially etching the plurality of source regions.

30. The manufacturing method of the semiconductor device according to claim 26, wherein the auxiliary doping source region is provided in plural.
